(19) United States
(12) Patent Application Publication
(10) Pub. No.: US 2014/0308436 A1
(43) Pub. Date: Oct. 16, 2014

(54) TRANSPARENT ELECTRODE, MANUFACTURING METHOD OF THE SAME AND ORGANIC ELECTROLUMINESCENCE ELEMENT

(71) Applicant: Konica Minolta, Inc., Tokyo (JP)

(72) Inventors: Kazuaki NAKAMURA, Tokyo (JP); Norio MIURA, Sagamihara-shi (JP)

(21) Appl. No.: 14/324,539

(22) Filed: Jul. 7, 2014

Related U.S. Application Data
(62) Division of application No. 12/869,203, filed on Aug. 26, 2010.

(30) Foreign Application Priority Data
Aug. 31, 2009 (JP) 2009-199580

(51) Int. Cl. H05B 33/10

(52) U.S. Cl. CPC H05B 33/10
USPC 427/108

(57) ABSTRACT

Provided is a transparent electrode containing a transparent substrate having thereon a transparent conductive layer containing a conductive fiber, a conductive polymer and a water soluble binder resin, wherein the water soluble binder resin contains a low molecular weight component in an amount of 0 to 5 weight % based on a weight of the water soluble binder resin, provided that the low molecular weight component has a number average molecular weight of 1,000 or less measured by GPC.

### CROSS REFERENCE TO RELATED APPLICATION

This application is based on Japanese Patent Application No. 2009-199580 filed on Aug. 31, 2009 with Japan Patent Office, the entire content of which is hereby incorporated by reference.

### TECHNICAL FIELD

The present invention relates to a transparent electrode, a method for manufacturing the same and an organic electroluminescence element (hereafter it is called as an organic EL element) using the same which are appropriately employable in various fields such as liquid crystal display elements, organic luminescence elements, inorganic electroluminescence elements, solar cells, electromagnetic wave shields, electronic papers or touch panels.

### BACKGROUND

In recent years, along with an increased demand for thinner TVs, there have been developed display technologies of various systems such as liquid crystals, plasma, organic electroluminescence, and field emission. In any of the displays which differ in the display system, transparent electrodes are incorporated therein as an essential constituting technology. Further, other than TVs, in touch panels, cellular phones, electronic paper, various solar cells, and various electroluminescence controlling elements, transparent electrodes have become an indispensable technical component.

Conventionally, as a transparent electrode, there has been mainly used an ITO transparent electrode having an indium-tin complex oxide (ITO) membrane produced by a vacuum deposition method or a sputtering process on transparent base materials, such as glass and a transparent plastic film. However, the indium used for ITO is a rare metal, and using no indium is desired by a substantial rise in prices. Moreover, it is required the manufacturing research and engineering of producing with a “roll-to-roll” method using a flexible base in connection with a display having a larger size, and improvement of productivity.

In recent years, there were disclosed technologies employing conductive fibers. It was proposed to form a transparent electrode in such a manner that some of a conductive fiber are fixed to a substrate by employing the transparent resin film and some of the conductive fibers are exposed or form projections on the surface of the transparent resin film (for example, refer to Patent document 1). However, the transparent electrode constituted as above only had electro-conductivity at the projected portion of the conducted fibers on the surface. This method had the problems to be solved that it cannot be applied to a flat electrode which is required to exhibit a uniform conductivity on the entire surface of the electrode.

Moreover, there was proposed a transparent flat electrode with a smooth electrode surface produced by overcoating polyurethane on the silver nanowires applied on a transparent substrate (for example, refer to Patent document 2). However, when the coating type organic EL element was laminated on this transparent electrode, it was revealed that it showed deteriorated surface lighting property and insufficient luminescence lifetime.

As for the average surface smoothness (Ra) of an ITO transparent conducting film surface used for an organic electroluminescence element, a smooth electrode of 10 nm or less is usually used. When the organic electroluminescence element was produced using the electrode in which a projection exists in a transparent electrode surface described in the above-mentioned Patent documents 1 and 2, there was a problem of short-circuiting with projections as the starting point, such as a short circuit between an anode and a cathode, and it had the problem that this phenomenon became outstanding further, under the ambience of the elevated temperature and high-humidity. Moreover, between projections, there exists a transparent resin, and it had problem that the function as a flat electrode was not fully obtained.

Moreover, when the transparent electrode produced by applying an overcoat layer made of an acrylic monomer or a dimer on a silver wire followed by hardening like the above-mentioned patent document 2 was used, the remaining monomer, oligomer or a low molecular weight component will be generated, and they will be spread between layers to result in deteriorating remarkably the lifetime of the organic EL element.

As forming transparent electrodes excellent in productivity, there were disclosed methods of applying a coating liquid prepared by dissolving or dispersing conductive polymer materials represented by π-conjugated polymers with coating or printing to form a transparent electrode (for example, refer to Patent document 3). Moreover, there were proposed transparent electrodes formed by laminating electrical conductive polymers on silver nanowires (for example, refer to Patent document 4). However, when compared to metal oxide transparent-electrodes such as ITO, which is prepared by a vacuum film preparing method, they exhibited lower electrical conductivity and degraded transparency. There remain problems to achieve both high transparency and high electrical conductivity at the same time.

Patent document 1: Japanese Patent Application Publication (hereafter it is called as JP-A) No. 2006-519712

Patent document 2: US 2007/0074316

Patent document 3: JP-A No. 6-273964

Patent document 4: US 2008/0259262

### SUMMARY

The present invention was made in view of the above-mentioned problems. An object of the present invention is to provide a transparent electrode which exhibits high conductivity and high transparency even if it is subjected to an environmental test under an elevated temperature and high humidity as well as shows good surface smoothness. An object of the present invention is also to provide a production method of the aforesaid transparent electrode. An object of the present invention is further to provide and an organic electroluminescence element excellent in the luminescence homogeneity using this transparent electrode.

In order to solve the aforesaid problems, the present invention has been achieved. It was found that the transparent electrode having a transparent conductive layer made of a water soluble binder resin containing a reduced amount of a low molecular weight component contained in the water soluble binder resin exhibits high stability of conductivity and smoothness after it is subjected to a forced aging test of high temperature and high humidity. It was also found that the organic electroluminescence element using the same transparent electrode exhibits high stability after forced aging test.

The above problems related to the present invention can be solved by the following embodiments.
1. A transparent electrode comprising a transparent substrate having thereon a transparent conductive layer containing a conductive fiber, a conductive polymer and a water soluble binder resin,

wherein the water soluble binder resin contains a low molecular weight component in an amount of 0 to 5 weight % based on a weight of the water soluble binder resin, provided that the low molecular weight component has a number average molecular weight of 1,000 or less measured by GPC.
2. A transparent electrode comprising a transparent substrate having thereon a first transparent conductive layer containing a conductive fiber and a second transparent conductive layer containing a conductive polymer and a water soluble binder resin in that order,

wherein the water soluble binder resin contains a low molecular weight component in an amount of 0 to 5 weight % based on a weight of the water soluble binder resin, provided that the low molecular weight component has a number average molecular weight of 1,000 or less measured by GPC.
3. The transparent electrode of the above-described items 1 or 2,

wherein at least one hydroxyl group is contained in a recurring unit which forms the water soluble binder resin.
4. The transparent electrode of any one of the above-described items 1 to 3,

wherein the water soluble binder resin contains a structure represented by Formula (1).

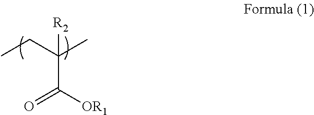

In Formula (1), R₁ represents a group which contains at least one hydroxyl group, and R₂ represents a hydrogen atom or a methyl group.
5. The transparent electrode of any one of the above-described items 1 to 4,

wherein the conductive fiber is a silver nanowire.
6. An electroluminescence element comprising the transparent electrode of any one of the above-described items 1 to 5.
7. A method for forming a transparent electrode comprising a step of

applying an aqueous dispersion containing water, a conductive fiber, a conductive polymer and a water soluble binder resin on a transparent substrate to form a transparent conductive layer,

wherein the water soluble binder resin contains a low molecular weight component in an amount of 0 to 5 weight % based on a weight of the water soluble binder resin, provided that the low molecular weight component has a number average molecular weight of 1,000 or less measured by GPC.
8. A method for forming a transparent electrode comprising the sequential steps of:

applying a first coating liquid containing a conductive fiber on a transparent substrate to form a first transparent conductive layer; and

applying a second coating liquid (an aqueous dispersion) containing water, a conductive polymer and a water soluble binder resin on the first transparent conductive layer to form a second transparent conductive layer,

wherein the water soluble binder resin contains a low molecular weight component in an amount of 0 to 5 weight % based on a weight of the water soluble binder resin, provided that the low molecular weight component has a number average molecular weight of 1,000 or less measured by GPC.
9. The method for forming a transparent electrode of the above-described items 7 or 8,

wherein at least one hydroxyl group is contained in a recurring unit which forms the water soluble binder resin.
10. The method for forming a transparent electrode of any one of the above-described items 7 to 9,

wherein the water soluble binder resin contains a structure represented by Formula (1).

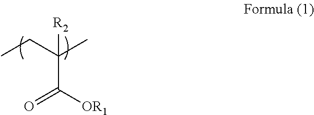

In Formula (1), R₁ represents a group which contains at least one hydroxyl group, and R₂ represents a hydrogen atom or a methyl group.
11. The method for forming a transparent electrode of any one of the above-described items 7 to 10,

wherein the conductive fiber is a silver nanowire.

According to the present invention, it is possible to provide a transparent electrode which exhibits high conductivity and high transparency even if it is subjected to an environmental test under an elevated temperature and high humidity as well as shows good surface smoothness. And it is also possible to provide a production method of the aforesaid transparent electrode and an organic electroluminescence element excellent in the luminescence homogeneity using this transparent electrode.

### BRIEF DESCRIPTION OF THE DRAWINGS

FIGS. 1A to 1C are schematic diagrams showing the structure of the transparent electrode of the present invention.

### DESCRIPTION OF THE PREFERRED EMBODIMENTS

The embodiments to carry out the present invention are described in the following, however, the present invention is not limited to these.

The transparent electrode of the present invention contains a transparent substrate having thereon a transparent conductive layer containing a conductive fiber, a conductive polymer and a water soluble binder resin, and it is characterized in that the water soluble binder resin contains a low molecular weight component in an amount of 0 to 5 weight % based on the weight of the water soluble binder resin, provided that the low molecular weight component has the number average molecular weight of 1,000 or less measured by GPC.

Another embodiment of the transparent electrode of the present invention contains a transparent substrate having thereon a first transparent conductive layer containing a conductive fiber and a second transparent conductive layer containing a conductive polymer and a water soluble binder resin in that order, and it is characterized in that the water soluble binder resin contains a low molecular weight component in an amount of 0 to 5 weight % based on the weight of the water soluble binder resin, provided that the low molecular weight component has the number average molecular weight of 1,000 or less measured by GPC.

In the present invention, it is possible to obtain a transparent electrode exhibiting high conductivity, high transparency and good surface smoothness even after subjected to the environmental test under an elevated temperature and high humidity environment. Further, it is possible to obtain an organic electroluminescence element exhibiting high luminescence homogeneity and excellent in stability using the aforesaid transparent electrode.

Hereafter, there will be described the present invention and its composition. Especially, the best embodiment to carry out the present invention will be described.

### [Transparent Substrate]

In the present invention, “transparent” indicates a property which exhibits the total optical transmittance in the visible wavelength range of 60% or more when it is measured by the method based on “The test method of the total optical transmittance of a plastic transparent material” of JIS K 7361-1 (it corresponds to ISO 13468-1).

Transparent substrates employed in the present invention are not particularly limited as long as they exhibit high optical transparency. For example, appropriate substrates listed are glass substrates, resin substrates, and resin films in view of excellent hardness and easy formation of a conductive layer on their surfaces. However, in view of low weight and high flexibility, it is preferable to employ the transparent resin films.

Transparent resin films preferably employed in the present invention are not particularly limited, and their materials, shape, structure and thickness may be selected from those known in the art. Examples of the transparent resin films includes: polyester film (e.g., polyethylene terephthalate (PET) film, polyethylene naphthalate film, modified polyester film), polyolefin film (e.g., polyethylene (PE) film, polypropylene (PP) film, polystyrene film, cycloolefin resin film), vinyl resin film (e. g., polyvinyl chloride film, polyvinylidene chloride film), polyether ether ketone (PEEK) film, polysulfone (PSF) film, polyethersulfone (PES) film, polycarbonate(PC) film, polyamide film, polyimide film, acrylic film, and triacetyl cellulose (TAC) film. If the resin films have the transmittance of 80% or more in the visible wavelength (380-780 nm), they are preferably applicable to the transparent resin film of the present invention. It is especially preferable that they are a biaxially-drawn polyethylene terephthalate film, a biaxially-drawn polyethylene naphthalate film, a polyethersulfone film, and a polycarbonate film from a viewpoint of transparency, heat resistance, easy handling, strength and cost. Furthermore, it is more preferable that they are biaxially-drawn polyethylene terephthalate film and a biaxially-drawn polyethylene naphthalate film.

In order to secure the wettability and adhesion property of a coating solution, surface treatment can be performed and an adhesion assisting layer may be provided on the transparent substrate used for the present invention. A well-known technique can be used conventionally with respect to surface treatment or an adhesion assisting layer. Examples of surface treatment include: surface activating treatment such as: corona discharge treatment, flame treatment, ultraviolet treatment, high-frequency wave treatment, glow discharge process, active plasma treatment and laser treatment. Examples of materials for an adhesion assisting layer include: polyester, polyamide, polyurethane, vinyl copolymer, butadiene copolymer, acrylic copolymer, vinylidene copolymer and epoxy copolymer. When a transparent resin film is a biaxially-drawn polyethylene terephthalate film, it is more preferable to set the refractive index of the adhesion assisting layer which adjoins the transparent resin film to be 1.57-1.63 so as to reduce the interface reflection with the film substrate and the adhesion assisting layer and to result in improving transmittance. Adjusting a refractive index can be achieved by adjusting suitably the relation of the content of tin oxide sol or a cerium oxide sol which has a comparatively high refractive index with respect to the content of the binder resin, and then coating them on the film substrate. Although a single layer may be sufficient as the adhesion assisting, it may be the composition of two or more layers in order to raise adhesion property. Moreover, a bather coat layer may be beforehand formed in the transparent substrate, and a hard coat layer may be beforehand formed in the opposite side on which a transparent conductive layer is transferred.

### [Transparent Electrode]

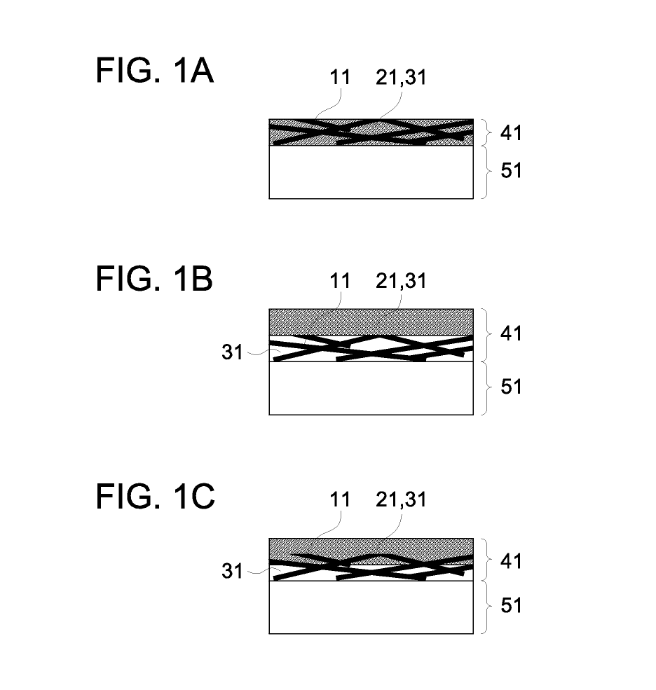

The schematic diagram showing the structure of the transparent electrode of the present invention is shown in FIGS. 1A to 1C.

FIG. 1A is a structural diagram showing a typical transparent electrode of the present invention. It has transparent conductive layer 41 on transparent substrate 51, and this transparent conductive layer 41 is composed of at least conductive fiber 11, conductive polymer 21 and water soluble bonder resin 31. In the present invention, there is no restriction in particular to other composition.

FIG. 1B is a structural diagram showing another typical transparent electrode of the present invention. It has transparent conductive layer 41 on transparent substrate 51, and this transparent conductive layer 41 is composed of: a first transparent conductive layer containing conductive fiber 11; and a second transparent conductive layer containing at least conductive polymer 21 and water soluble bonder resin 31. The first transparent conductive layer and the second transparent conductive layer are laminated on the transparent substrate 51 in that order. In the present invention, there is no restriction in particular to other composition.

FIG. 1C is a structural diagram showing another typical transparent electrode of the present invention. It has transparent conductive layer 41 on transparent substrate 51, and this transparent conductive layer 41 is composed of a first transparent conductive layer containing conductive fiber 11 (provided that the conductive fiber 11 is protruded from the first transparent conductive layer); and a second transparent conductive layer containing at least conductive polymer 21 and water soluble bonder resin 31. The first transparent conductive layer and the second transparent conductive layer are laminated on the transparent substrate 51 in that order. In the present invention, there is no restriction in particular to other composition.

In addition, surface treatment can be performed to a transparent substrate as mentioned above, or a various functionality layer can be prepared according to the object.

The total optical transmittance of the transparent electrode of the present invention is preferably at least 60%, it is more preferably at least 70%, but it is still most preferably at least 80%. It is possible to determine the total optical transmittance based on methods known in the art, employing a spectrophotometer. Further, the electrical resistance value of the transparent conductive layer of the transparent electrode is preferably at most 1,000 Ω/□ in terms of surface resistivity, it is more preferably at most 100 Ω/□. In order to apply to electric current driving type optoelectronic devices, it is preferably to be at most 50 Ω/□, and it is specifically preferable to be at most 10 Ω/□. When the transparent electrode has an electrical resistance value of 1,000 Ω/□ or less, it is preferable since it can be used as a transparent electrode for a various kinds of electric current driving type optoelectronic devices. It is possible to determine the above surface resistivity, for example, based on JIS K7194: 1994 (Test method for resistivity of conductive plastics with a 4-pin probe measurement method) or ASTM D257. Further, it is also possible to conveniently determine the surface resistivity employing a commercially available surface resistivity meter.

The thickness of the transparent electrode of the present invention is not particularly limited, and it is possible to appropriately select the thickness depending on intended purposes. However, commonly the thickness is preferably at most 10 μm. The thickness is more preferably thinner since transparency and transparency are thereby improved in relation to the thickness.

### [Transparent Conductive Layer]

In one of the embodiments of the present invention, it is preferable that the conductive fiber is at least one selected from the group consisting of a metal nanowire and a carbon nanotube, and that the conductive material is at least one selected from the group consisting of a conductive polymer and a conductive metal oxide particle.

The transparent conductive layer of the present invention may contain a transparent binder material and an additive besides the conductive fiber and the conductive material. If it is a transparent resin which can form a coating solution, there will be no restriction in particular as a transparent binder material. Examples of the transparent resin include: polyester resin, polystyrene resin, acrylic resin, polyurethane resin, acrylic urethane resin, polycarbonate resin, cellulose resin and butyral resin. It can be used singly, or it can be used in combination of two or more.

The thickness of the transparent conductive layer of the present invention varies depending on the shape and the content of employed conductive fibers, but as a rough target, it is preferably from at least the average diameter of conductive fibers to at most 500 nm. It is preferable to decrease the thickness of the transparent conductive layer of the present invention with the pressing method which will be described later, since it is possible to closely form the network of the conductive fibers in the layer thickness direction.

### [Surface Smoothness]

In the present invention, Ry and Ra each respectively show the surface smoothness of the surface of a transparent conductive layer. They indicate respectively the following meanings: Ry=a maximum height (the vertical interval between the summit part and a bottom part in the surface); and Ra=an arithmetic mean roughness. They are specified based on TIS B601 (1994). The transparent electrode of the present invention preferably has the surface smoothness of the surface of the transparent conductive layer of Ry≦50 nm and at the same time it is preferable to have the surface smoothness of Ra≦5 nm. In the present invention, a commercially available atomic force microscope (AFM) can be used for measurement of Ry and Ra. For example, they can be measured by the following ways.

As an AFM, SPI3800N probe station and an SPA400 multifunctional-capability type module made by Seiko Instruments Co., Ltd., are used. The sample cut off in a square having a side of about 1 cm is set on a level sample stand on a piezo scanner, then, a cantilever is allowed to approach to a surface of the sample. When the cantilever reaches the region where an atomic force can function, the cantilever is scanned in the XY direction, and irregularity of the surface of the sample is caught by displacement of the piezo element in the Z direction. A piezo scanner which can scan the XY direction of 20 μm and the Z direction of 2 μm is used for the measurement. A cantilever used is silicon cantilever SI-DF20 made by Seiko Instruments Co., Ltd., and measurement is done in a DFM mode (Dynamic Force Mode) using the resonant frequency of 120-150 kHz, the spring constant of 12-20 N/m. The portion of 80 x 80 pm is measured with the scanning frequency of 1 Hz.

In the present invention, the value Ry is more preferably to be 50 nm or less, and it is still more preferably to be 40 nm or less. Similarly, the value Ra is more preferably to be 10 nm or less, and i it is still more preferably to be 5 nm or less.

### [Conductive Fiber]

The conductive fiber concerning the present invention has conductivity, and has a form with a length long enough compared with a diameter (thickness). It is thought that the conductive fiber of the present invention forms a three-dimensional conductive network when a conductive fiber contacts each other in a transparent conductive layer, and it functions as an auxiliary electrode. Therefore, it is preferable to use a conductive fiber having a longer length since it is advantageous to form a conductive network. On the other hand, when a conductive fiber becomes long, a conductive fiber will become entangled resulting in forming an aggregate, which may deteriorate an optical property. It is preferable to use the conductive fiber of the optimal average aspect ratio (aspect ratio=length/diameter) according to the conductive fiber to be used, since the rigidity of a conductive fiber, a diameter or other properties may affect the formation of the conductive network and aggregate. As for an average aspect ratio, as a near rough indication, it is preferable to be 10-10,000.

As a form of a conductive fiber, there are known several shapes such as a hollow tube, a wire and a fiber. For example, there are an organic fiber coated with metal, an inorganic fiber, a conductive metal oxide fiber, a metal nanowire, a carbon fiber and a carbon nanotube. In the present invention, it is preferable that the thickness of a conductive fiber is 300 nm or less from a viewpoint of transparency. In addition, in order to also satisfy conductivity of a conductive fiber, it is preferable that the used conductive fiber is at least one selected from the group consisting of a metal nanowire and a carbon nanotube. Furthermore, a silver nanowire can be most preferably used from a viewpoint of cost (a material cost, a cost of production) and properties (electro-conductivity, transparency and flexibility).

In the present invention, it is possible to determine the above average diameter and average aspect ratio of the conductive fibers as follows. A sufficient number of electron microscopic images are taken. Subsequently, each of the conductive fiber images is measured and the arithmetic average is obtained. The length of conductive fibers should fundamentally be determined in a stretched state to become a straight line. In reality, in most cases, they are curved. Consequently, by employing electron microscopic images, the projected diameter and projected area of each of the nanowires were calculated employing an image analysis apparatus and calculation is carried out while assuming a cylindrical column (length=projected area/projected diameter). A relative standard deviation of length or diameter is represented with a value obtained from the standard deviation value of the measured values divided by the average value of the measured values, which is multiplied by 100. The number of nanowires to be measured is preferably at least 100, but is more preferably at least 300.

Relative standard deviation (%)=(Standard deviation value of the measured values/average value of the measured values)×100

### [Metal Nanowires]

Generally, metal nanowires indicate a linear structure composed of a metallic element as a main structural element. In particular, the metal nanowires in the present invention indicate a linear structure having a diameter of from an atomic scale to a nanometer (nm) size.

In order to form a long conductive path by one metal nanowire, a metal nanowire applied to the conductive fibers concerning the present invention is preferably have an average length of 3 μm or more, more preferably it is 3-500 μm, and still more it is 3-300 μm. In addition, the relative standard deviation of the length of the conductive fibers is preferably 40% or less. Moreover, from a viewpoint of transparency, a smaller average diameter is preferable, on the other hand, a larger average diameter is preferable from a conductive viewpoint. In the present invention, 10-300 nm is preferable as an average diameter of metal nanowires, and it is more preferable to be 30-200 nm. Further, the relative standard deviation of the diameter is preferably to be 20% or less.

There is no restriction in particular to the metal composition of the metal nanowire of the present invention, and it can be composed of one sort or two or more metals of noble metal elements or base metal elements. It is preferable that it contains at least one sort of metal selected from the group consisting of noble metals (for example, gold, platinum, silver, palladium, rhodium, iridium, ruthenium and osmium), iron, cobalt, copper and tin. It is more preferable that silver is included in it at least from a conductive viewpoint. Moreover, for the purpose of achieving compatibility of conductivity and stability (sulfuration resistance and oxidation resistance of metal nanowire and migration resistance of metal nanowire), it is also preferable that it contains silver and at least one sort of metal belonging to the noble metal except silver. When the metal nanowire of the present invention contains two or more kinds of metallic elements, metal composition may be different between the surface and the inside of metal nanowire, and the whole metal nanowire may have the same metal composition.

In the present invention, there is no restriction in particular to the production means of metal nanowires. It is possible to prepare metal nanowires via various methods such as a liquid phase method or a gas phase method. For example, the manufacturing method of Ag nanowires may be referred to Adv. Mater. 2002, 14, 833-837 and Chem. Mater. 2002, 14, 4736-4745; a manufacturing method of Au nanowires may be referred to JP-A No. 2006-233252; the manufacturing method of Cu nanowires may be referred to JP-A No. 2002-266007; while the manufacturing method of Co nanowires may be referred to JP-A No. 2004-149871. Specifically, the manufacturing methods of Ag nanowires, described in Adv. Mater. 2002, 14, 833-837 and Chem. Mater. 2002, 14, 4736-4745, may be preferably employed as a manufacturing method of the metal nanowires according to the present invention, since via those methods, it is possible to simply prepare a large amount of Ag nanowires in an aqueous system and the electrical conductivity of silver is highest of all metals.

### [Carbon Nanotube]

Carbon nanotubes are a carbon fiber material having a cylindrical shape formed with graphite-like carbon atom surfaces (graphene seats) of a thickness of several atomic layers. Carbon nanotubes are divided roughly into a single layer nanotube (SWNT) and a multilayer nanotube (MWNT) from the composition numbers of the peripheral walls of the tube. Moreover, it is divided into a chiral (spiral) type, a zigzag type, and an armchair type from the difference in the structure of a graphene seat, thus there are known various types of carbon nanotube.

As a carbon nanotube applied to the conductive fiber concerning the present invention, any types of carbon nanotube can be used, and more than one type of these various carbon nanotubes may be used by mixing. In the present invention, it is preferable to employ single layer nanotubes which excel in electro-conductivity, and further, it is preferable to employ metallic armchair type single layer carbon nanotubes.

In order to form a long conductive path by one carbon nanotube, the shape of the carbon nanotube of the present invention is preferably have a large aspect ratio (aspect ratio=length/diameter), namely, it is preferable that the carbon nanotube is thin and long single layer carbon nanotube. For example, carbon nanotubes having an aspect ration of 102, more preferably having an aspect ratio 103 or more can be cited for preferable carbon nanotubes. An average length of carbon nanotubes is preferably 3 μm or more, and more preferably it is 3-500 μm, and still more preferably it is 3-300 μm. In addition, the relative standard deviation of the length is preferably to be 40% or less. Moreover, an average diameter is preferably to be smaller than 100 nm, more preferably it is 1-50 nm, and still more preferably, it is 1-30 nm. In addition, the relative standard deviation of the diameter is preferably to be 20% or less.

The production method of the carbon nanotubes used in the present invention is not limited in particular. It can be used well-known means, such as catalytic hydrogen reduction of carbon dioxide, arc discharge process, laser evaporating method, CVD method, vapor growth method, and HiPco method in which carbon monoxide is allowed to react with an iron catalyst at an elevated-temperature with a high pressure and make it grow up in a gas phase. Moreover, in order to remove the residues of the reaction, such as byproducts and catalyst metals, it is preferable to highly purify the carbon nanotubes by various refining processes, such as with washing method, centrifuge method, filtration, oxidation method, and chromatography so as to fully exhibiting the various functions of the carbon nanotubes.

### [Conductive Polymer]

Examples of a conductive polymer employed for the conductive material in the present invention include compounds selected from the group consisting of each of the derivatives of polypyrrole, polyaniline, polythiophene, polythienylene vinylene, polyazulene, polyisothianaphthene, polycarbazole, polyacetylene, polyphenylene, polyphenylene vinylene, polyacene, polyphenyl acetylene and polynaphthalene.

The conductive material of the present invention may incorporate only one type of a conductive polymer alone or at least two types of conductive polymers in combination. In view of electrical conductivity and transparency, it is more preferable to incorporate at least one compound selected from the group consisting of polyaniline having the repeated unit represented by the following Formula (I) and/or the following Formula (II) and derivatives thereof, polypyrrole derivatives having the repeated unit represented by the following Formula (III), and polythiophene derivatives having the repeated unit represented by the following Formula (IV).

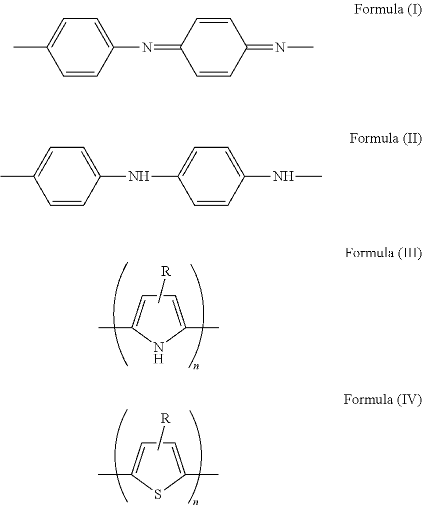

In above Formula (III) and Formula (IV), R is primarily a linear organic substituent, which is preferably an alkyl group, an alkoxy group, or an allyl group, or a combination thereof. Further, these may be combined with a sulfonate group, an ester group, or an amido group or a combination thereof These may be usable when properties as a soluble conductive polymer are not lost. Still further, “n” is an integer.

Conductive polymers employed in the present invention may be subjected to doping treatment to further enhance electro-conductivity. Examples of a dopant used for conductive polymers include at least one selected from the group consisting of sulfonic acids (hereinafter referred to as “long chain sulfonic acids”) having a hydrocarbon group with 6-30 carbon atoms or polymers thereof (for example, polystyrenesulfonic acid) or derivatives thereof; halogens, Lewis acids, protonic acids, transition metal halides, transition metal compounds, alkaline metals, alkaline earth metals, MClO₄ (M=Li⁺ or Na⁺), R₄N⁺ (R=CH₃, C₄H₉, or C₆H₅), or R₄P⁺ (R=CH₃, C₄H₉, or C₆H₅). Of these, the above long chain sulfonic acid is preferred.

Further, the dopants used for conductive polymers may be incorporated into fullerenes such as hydrogenated fullerene, hydroxylated fullerene, or sulfonated fullerene. In the transparent conductive layer of the present invention, the content of the above dopants is preferably at least 0.001 part by weight with respect to 100 parts by weight of the conductive polymers, but it is more preferably at least 0.5 part by weight.

The conductive polymers of the present invention may incorporate at least one dopant selected from the group consisting of a long chain sulfonic acid, polymers of the long chain sulfonic acid (for example, polystyrenesulfonic acid), halogens, Lewis acids, protonic acids, transition metal halides, transition metal compounds, alkaline metals, alkaline earth metals, MClO₄, R₄N⁺, and R₄P⁺, together with fullerenes.

As the conductive polymers according to the present invention, employed may be conductive polymers modified via metal, disclosed in each of JP-A Nos. 2001-511581, 2004-99640 and 2007-165199.

Conductive materials which include conductive polymers according to the present invention may incorporate water soluble organic compounds. There are known compounds which exhibit effects to enhance electro-conductivity via addition to a conductive polymer, and they are occasionally called a 2^{nd} dopant (or a sensitizer). The 2^{nd} dopants which are usable in the present invention are not particularly limited, and it is possible to appropriately select them from those known in the art. Preferred examples include oxygen-containing compounds such as dimethyl sulfoxide (DMSO) and diethylene glycol.

The content of the above-described 2^{nd} dopants in the conductive materials incorporating a conductive polymer of the present invention is preferably at least 0.001 part by weight with respect to 100 parts by weight of the conductive polymer, it is more preferably 0.01-50 parts by weight, but it is most preferably 0.01-10 parts by weight.

In order to assure film forming properties and film strength, the conductive materials incorporating a conductive polymer of to the present invention may incorporate transparent resin components and additives, other than the above-described conductive polymers. With regard to transparent resin components, the resin components are not particularly limited as long as they are compatible with or mix dispersible with the conductive polymers. They may be thermally curable resins or thermoplastic resins. Examples of the transparent resin include: polyester resin (e.g., polyethylene terephthalate, polybutylene terephthalate and polyethylene naphthalate), polyimide resin (e.g., polyimide resin and polyamideimide resin), polyamide resin (e.g., polyamide 6, polyamide 6,6, polyamide 12 and polyamide 11), fluororesin (e.g., polyvinylidene fluoride, polyvinyl fluoride, polytetrafluoroethylene, ethylene-tetrafluoroethylene copolymer, polychlorotrifluoroethylene), vinyl resin (e.g., polyvinyl alcohol, polyvinyl ether, polyvinyl butyral, polyvinyl acetate, polyvinyl chloride), epoxy resin, xylene resin, aramid resin, polyurethane resin, polyurea resin, melamine resin, phenol resin, polyether, acrylic resin and copolymers thereof.

A polyanion which may be used in the present invention can be a compound selected from the group consisting of a polymer carboxylic acid, a polymer sulfonic acid and their salts. It is preferable to use a polymer sulfonic acid and a salt thereof. A polyanion may be contained singly and may be contained in combination of two or more kinds. Moreover, a polyanion may form a copolymer of a structural unit which has carboxylic acid and sulfonic acid with a monomer which does not have acid residue, for example, a acrylate, methacrylate or styrene.

Examples of a polymer carboxylic acid, a polymer sulfonic acid and their salts include: polyacrylic acid, polymethacrylic acid, polymaleic acid, polymer sulfonic acid, polystyrene sulfonate, polyvinyl sulfonic acid and the salts of these compounds. Polystyrene sulfonate and its salt are preferably used.

### [Water Soluble Binder Resin]

The water soluble binder resin of the present invention is a resin which can be dissolved in an amount of 0.001 g or more in 100 g of water at 25° C. The above-mentioned dissolution can be measured with a haze meter and a turbidimeter.

It is preferable that the water soluble binder resin of the present invention is transparent.

As a water soluble binder of the present invention, there is no restriction in particular as long as it is a medium to form a film such as a natural polymer, a synthetic resin, a synthetic polymer, a synthetic copolymer, and other materials. Examples the water soluble binder include: gelatin, casein, starch, gum arabic, poly(vinyl alcohol), poly(vinyl pyrrolidone), cellulose derivatives (e. g., carboxymethyl ether cellulose, hydroxyethyl cellulose, methylhydroxyethyl ether cellulose), chitosan, dextran, guar gum, poly (acrylamide), poly(acrylamide acrylic acid), poly(acrylic acid), poly(methacrylic acid), poly(allylamine), poly(butadiene-maleic anhydride), poly(n-butyl acrylate 2-methacryloyl trimethyl ammonium bromide), (3-chloro-2-hydroxypropyl-2-methacryloxy trimethyl ammonium bromide), poly(2-dimethylaminoethyl methacrylate), poly(ethylene glycol), poly(ethylene glycol)-bisphenol A-diglycidyl ether adduct, poly(ethylene glycol) bis-2-aminoethyl, poly(ethylene glycol) dimethyl ether, poly(ethylene glycol) monocarboxymethyl ether monomethyl ether, poly(ethylene glycol) monomethyl ether, poly(ethylene oxide), poly(ethylene oxide-b-propylene oxide), polyethyleneimine, poly(2-ethyl-2-oxazoline), poly(1-glycerol methacrylate), poly(2-hydroxyethyl acrylate), poly(2-ethyl methacrylate), poly(2-hydroxyethyl methacrylate methacrylic acid), poly(maleic acid), poly(methacrylamide), poly(2-metahcryloxyethyl trimethyl ammonium bromide), poly(N-iso-propylacrylamide), poly(styrene sulfonic acid), poly(N-vinylacetamide), poly(N-methyl-N-vinylacetamide), poly(vinylamine), poly(2-vinyl-1-methyl pyridinium bromide), poly(phosphoric acid), poly(2-vinylpyridine), poly(4-vinylpyridine), poly(2-vinylpyridine N-oxide) and poly (vinylsulfonic acid). In the above-mentioned binders, the polymer which has a carboxyl group, a sulfo group, or a phosphoric acid group, may have salt of such as lithium, sodium, and potassium, and the polymer which has a nitrogen atom may have the structure of a hydrochloride. Moreover, a melamine resin, a urea resin, and a glyoxal resin, which are thermosetting resin can be cited. The above-mentioned binder can be used singly or two or more sorts may be used in combination.

Among water soluble binder resins of the present invention, preferable compounds are: gelatin, poly(vinyl alcohol), poly(vinyl pyrrolidone), cellulose derivatives, poly(acrylic acid), poly(ethylene glycol), poly(2-hydroxyethyl acrylate), poly(2-hydroxyethyl methacrylate), poly(2-hydroxypropyl methacrylate) and poly(vinylsulfonic acid). It may be used commercially available compounds such as: poly(vinyl pyrrolidone) and poly(vinyl alcohol) (made by Polysciences, Inc.); PVA 203, PVA 224, EXEVAL RS-4104 (made by Kuraray Co., Ltd.); and METOLOSE 90SH-100, METOLOSE 60SH-50, METOLOSE 60SH-06 (made by Shin-Etsu Chemical Co., Ltd.).

More preferable water soluble binder resins of the present invention contain a hydroxyl group in a recurring unit. Examples of such polymer include: poly(vinyl pyrrolidone), poly(vinyl alcohol), cellulose derivatives, poly(2-hydroxyethyl acrylate), poly(3-hydroxypropyl acrylate), poly(4-hydroxybutyl acrylate), poly(2-hydroxyethyl methacrylate) and poly(3-hydroxypropyl methacrylate). Still more preferably, the water soluble binder resins of the present invention are a water soluble binder resin containing a structural unit represented by Formula (1)

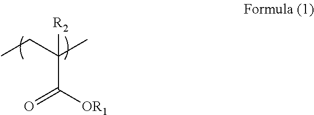

In Formula (1), R₁ represents a group which contains at least one hydroxyl group, and R₂ represents a hydrogen atom or a methyl group.

In the structural unit represented by Formula (1), R₁ represents a group which contains at least one hydroxyl group. Examples of a group represented by R₁ include: an alkyl group, a cycloalkyl group, an aryl group, a heterocycloalkyl group and a heteroaryl group. Preferable groups are an alkyl group, a cycloalkyl group and an aryl group. More preferable group is an alkyl group.

The above-described groups may be substituted with the following groups: an alkyl group, a cycloalkyl group, an aryl group, a heterocycloalkyl group, a heteroaryl group, a hydroxyl group, a halogen atom, an alkoxy group, an alkylthio group, an arylthio group, a cycloalkoxy group, an aryloxy group, an acyl group, an alkylcarbonamide group, an arylcarbonamide group, an alkylsulfonamide group, an arylsulfonamide group, an ureido group, an aralkyl group, a nitro group, an alkoxycarbonyl group, an aryloxycarbonyl group, an aralkyloxycarbonyl group, an alkylcarbamoyl group, an arylcarbamoyl group, an alkylsulfamoyl group, an arylsulfamoyl group, an acyloxy group, a alkenyl group, an alkynyl group, an alkylsulfonyl group, an arylsulfonyl group, an alkyloxysulfonyl group, an aryloxysulfonyl group, an alkylsulfonyloxy group and an arylsulfonyloxy group. Among them, preferable are a hydroxyl group and an alkyloxy group.

In the above-mentioned halogen atom includes: a fluorine atom, a chlorine atom, a bromine atom and iodine atom are contained.

The above-mentioned alkyl group may have a branch. A carbon atom number of the alkyl group is preferably 1-20, it is more preferably 1-12, and, it is still more preferably 1-8. Examples of the alkyl group contain: a methyl group, an ethyl group, a propyl group, an isopropyl group, a butyl group, t-butyl group, a hexyl group and an octyl group.

The above-mentioned cycloalkyl group has preferably a carbon atom number of 3-20, it is more preferably 3-12, and, it is still more preferably 3-8. Examples of the cycloalkyl group contain: a cyclopropyl group, a cyclobutyl group, a cyclopentyl group and a cyclohexyl group. The above-mentioned alkoxyl group may have a branch. The alkoxyl group has preferably a carbon atom number of 1-20, it is more preferably 1-12, it is still more preferably 1-6, and it is most preferably 1-4. Examples of the alkoxyl group contain: a methoxy group, an ethoxy group, 2-methoxyethoxy group, a 2-methoxy-2-ethoxyethoxy group, a butyloxygroup, a hexyloxygroup and an octyloxy group. Preferably it is an ethoxy group. The above-mentioned alkylthio group may have a branch. The alkylthio group has preferably a carbon atom number of 1-20, it is more preferably 1-12, it is still more preferably 1-6, and it is most preferably 1-4. Examples of the alkylthio group contain: a methylthio group and an ethylthio group. The above-mentioned arylthio group has preferably 6-20, it is more preferably a carbon atom number of 6-12. Examples of the arylthio group contain: a phenylthio group and a naphthylthio group. The above-mentioned cycloalkoxy group has preferably a carbon atom number of 3-12, it is more preferably 3-8. Examples of the cycloalkoxy group contain: a cyclopropoxy group, a cyclobutyloxy group, a cyclopentyloxy group and a cyclohexyloxy group. The above-mentioned aryl group has preferably a carbon atom number of 6-20, it is more preferably 6-12. Examples of the aryl group contain: a phenyl group and a naphthyl group. The above-mentioned aryloxy group has preferably a carbon atom number of 6-20, it is more preferably 6-12. Examples of the aryloxy group contain: a phenoxy group and a naphthoxy group. The above-mentioned heterocycloalkyl group has preferably a carbon atom number of 2-10, it is more preferably 3-5. Examples of the heterocycloalkyl group contain: a piperidino group, a dioxanyl group and 2-morpholinyl group. The above-mentioned heteroaryl group has preferably a carbon atom number of 3-20, it is more preferably 3-10. Examples of the heteroaryl group contain: a thienyl group and a pyridyl group. The above-mentioned acyl group has preferably a carbon atom number of 1-20, it is more preferably 1-12. Examples of the acyl group contain: a formyl group, an acetyl group and a benzoyl group. The above-mentioned alkylcarbonamide group has preferably a carbon atom number of 1-20, it is more preferably 1-12. Examples of the alkylcarbonamide group contain an acetoamide group. The above-mentioned arylcarbonamide group has preferably a carbon atom number of 1-20, it is more preferably 1-12. Examples of the arylcarbonamide group contain a benzamide group. The above-mentioned alkylsulfonamide group has preferably a carbon atom number of 1-20, it is more preferably 1-12. Examples of the alkylsulfonamide group contain a methanesufonamide group. The above-mentioned arylsulfonamide group has preferably a carbon atom number of 1-20, it is more preferably 1-12. Examples of the arylsulfonamide group contain: a benzenesulfonamide group and p-toluenesulfonamide. The above-mentioned aralkyl group has preferably a carbon atom number of 7-20, it is more preferably 7-12. Examples of the aralkyl group contain: a benzyl group, a phenethyl group and a naphthylmethyl group. The above-mentioned alkoxycarbonyl group has preferably a carbon atom number of 1-20, it is more preferably 2-12. Examples of the alkoxycarbonyl group contain a methoxycarbonyl group. The above-mentioned aryloxycarbonyl group has preferably a carbon atom number of 7-20, it is more preferably 7-12. Examples of the aryloxycarbonyl group contain a phenoxycarbonyl group. The above-mentioned aralkyloxycarbonyl group has preferably a carbon atom number of 8-20, it is more preferably 8-12. Examples of the aralkyloxycarbonyl group contain a benzyloxycarbonyl group. The above-mentioned acyloxy group has preferably a carbon atom number of 1-20, it is more preferably 2-12. Examples of the acyloxy group contain a acetoxy group and a benzoyloxy group. The above-mentioned alkenyl group has preferably a carbon atom number of 2-20, it is more preferably 2-12. Examples of the alkenyl group contain: a vinyl group, allyl group and an isopropenyl group. The above-mentioned alkynyl group has preferably a carbon atom number of 2-20, it is more preferably 2-12. Examples of the alkynyl group contain a ethynyl group. The above-mentioned alkylsulfonyl group has preferably a carbon atom number of 1-20, it is more preferably 1-12. Examples of the alkylsulfonyl group contain a methysulfonyl group and an ethysulfonyl group. The above-mentioned arylsulfonyl group has preferably a carbon atom number of 6-20, it is more preferably 6-12. Examples of the arylsulfonyl group contain a phenylsulfonyl group and a naphthylsulfonyl group. Examples of the alkynyl group contain a ethynyl group. The above-mentioned alkyloxysulfonyl group has preferably a carbon atom number of 1-20, it is more preferably 1-12. Examples of the alkyloxysulfonyl group contain a methoxysulfonyl group and an ethoxysulfonyl group. The above-mentioned aryloxysulfonyl group has preferably a carbon atom number of 6-20, it is more preferably 6-12. Examples of the aryloxysulfonyl group contain a phenoxysulfonyl group and a naphthoxysulfonyl group. The above-mentioned alkylsulfonyloxy group has preferably a carbon atom number of 1-20, it is more preferably 1-12. Examples of the alkylsulfonyloxy group contain a methylsulfonyloxy group and an ethylsulfonyloxy group.

The above-mentioned arylsulfonyloxy group has preferably a carbon atom number of 6-20, it is more preferably 6-12. Examples of the arylsulfonyloxy group contain a phenylsulfonyloxy group and a naphtylsulfonyloxy group. When a plurality of the substituent are contained, they may be the same or different. These substituents may be further substituted with a substituent.

In the structural unit represented by Formula (1), specific examples of R1 are: a 2-hydroxyethyl group, a 3-hydroxypropyl group, a 4-hydroxybutyl group and a 2,3-dihydroxypropyl. Preferable group is a 2-hydroxyethyl group. R2 represents a hydrogen atom or a methyl group.

The water soluble binder resin of the present invention is characterized in that it contains a low molecular weight component in an amount of 0 to 5 weight % based on the weight of the water soluble binder resin, provided that the a low molecular weight component has the number average molecular weight of 1,000 or less measured with GPC.

As methods to obtain the water soluble binder resin of the present invention include: a method to eliminate a low molecular weight component by a re-precipitation method or a preparative GPC, or by synthesizing a monodispersed polymer using a living polymerization; and a method to control formation of a low molecular weight component. The reprecipitation method is a way of dropping a solution of a polymer dissolved in a soluble solvent having a high solubility of the polymer into another solvent having a low solubility of the polymer to precipitate the polymer from the solvents and to remove low molecular weight components, such as a monomer, a catalyst and an oligomer. The preparative GPC can be carried out using, for example, a recycled preparative GPC LC-9100 (Japan Analytical Industry Co., Ltd). A solution which dissolves a polymer is allowed to pass though a polystyrene gel column to divide the polymer with molecular weight Thus the desired low molecular weight components can be cut. The living polymerization is a method in which formation of an initiation species can be kept constant during the reaction time, and there are few side reactions, such as a cessation reaction, and it will produce a polymer having a uniform molecular weight. Since the molecular weight can be controlled by the added amount of monomers, if the polymer having a molecular weight of 20,000 is synthesized, for example, the formation of low molecular weight components can be inhibited. From the viewpoint of manufacturing aptitude, the re-precipitating method and the living polymerization are desirable.

The measurement of the number average molecular weight and the molecular weight distribution of the water soluble binder resin concerning the present invention can be peg formed with generally known gel permeation chromatography (GPC). The solvents used for GPC are not specifically limited as long as they will dissolve the water soluble binder resin. Preferable solvents are THF, DMF and CH₂Cl₂. More preferable solvents are THF and DMF. Still more preferable solvent is THE Moreover, although the measuring temperature is not specifically limited, 40° C. is preferable.

The number average molecular weight of the water soluble binder resin concerning the present invention is preferably in the range of 3,000 to 2,000,000. It is more preferably in the range of 4,000 to 500,000. It is still more preferably in the range of 5,000 to 100,000.

The molecular weight distribution of the water soluble binder resin concerning the present invention is preferably from 1.01 to 1.30, and it is more preferably from 1.01 to 1.25.

The water soluble binder resin concerning the present invention contains a low molecular weight component in an amount of 0 to 5 weight %, wherein the low molecular weight component has the number average molecular weight of 1,000 or less measured by GPC.

The content of the low molecular weight component having the number average molecular weight of 1,000 or less can be measured from the distribution diagram obtained by GPC. The area of the number average molecular weight of 1,000 or less is integrated and it is divided by the whole area of the distribution diagram. The divided value is used as a content ratio of the low molecular weight component.

The water soluble binder resin concerning the present invention containing the structural unit represented by Formula (1) is preferably produced by living radical polymerization. The Examples which will be described later can be referred.

The solvents used in the living radical polymerization carried out to produce the water soluble binder resin concerning the present invention containing the structural unit represented by Formula (1) are not limited in particular as long as they are inert in the reaction conditions and can dissolve the monomer and the produced polymer. A mixed solvent made of water and an alcohol type solvent is preferably used.

The temperature at which the living radical polymerization is carried out to produce the water soluble binder resin concerning the present invention containing the structural unit represented by Formula (1) depends on the solvents used. Generally, the reaction is carried out at −10 to 250° C., preferably at 0 to 200° C., and more preferably at 10 to 100° C.

### [Manufacturing Methods]

In the production method of the transparent electrode of the present invention, there is no restriction in particular to the methods of forming the auxiliary electrode composed of conductive fibers, and the transparent conductive layer containing a conductive (or it may be called as “electro-conductive”) material on a transparent substrate. However, in view of productivity and production cost, electrode qualities such as smoothness and uniformity, as well as reduction of environmental load, in order to form the transparent conductive layer, it is preferable to employ liquid phase film forming methods such as coating methods or printing methods. As the coating method employed may be a roller coating method, a bar coating method, a dip coating method, a spin coating method, a casting method, a die coating method, a blade coating method, a bar coating method, a gravure coating method, a curtain coating method, a spray coating method, and a doctor coating method, while as the printing method employed may be a letterpress (typographic) printing method, a porous (screen) printing method, a lithographic (offset) printing method, an intaglio (gravure) printing, a spray printing method, and an ink-jet printing method. As preliminary treatment to enhance close contact and coatability, if desired, the surface of a mold-releasing substrate may be subjected to physical surface treatment such as corona discharge treatment or plasma discharge treatment.

In a manufacturing method of a transparent electrode of the present invention, the following methods can be cited as methods for forming a transparent conductive layer containing a conductive fiber, a conductive polymer and a water soluble binder.
(A) Coating an aqueous dispersion containing water, a conductive fiber, a conductive polymer and a water soluble binder resin on a transparent substrate to form a transparent conductive layer.
(B) Applying a coating liquid containing a conductive fiber on a transparent substrate to form a first transparent conductive layer; and then, applying an aqueous dispersion containing water, a conductive polymer and a water soluble binder resin on the first transparent conductive layer to form a second transparent conductive layer.
(C) Forming a transparent conductive layer containing a conductive fiber and a conductive material on a mold-releasing surface of a smooth mold-releasing substrate; and then the formed transparent conductive layer is transferred to a transparent substrate so as to form a first transparent conductive layer, followed by coating an aqueous dispersion containing a conductive polymer and a water soluble binder resin on the first transparent conductive layer so as to form a second transparent conductive layer.

In the above-described manufacturing method (A) of a transparent electrode, there are no limitations in particular in the added amounts of the conductive fiber, the conductive polymer and the water soluble binder resin. However, by considering the relationship of conductivity and transparency, the amount of the conductive fiber is preferably 0.50 g/m² or less, and it is more preferably 0.10 g/m² or less. The amount of the conductive polymer is preferably 50 times or less of the weight of the conductive fiber as a solid portion, it is more preferably 10 times or less, and it is still more preferably 5 times or less. The amount of the water soluble binder resin is preferably 5 times or less of the weight of the conductive binder as a solid portion, and it is more preferably 3 times or less.

In the above-described manufacturing method (B) of a transparent electrode, the added amounts of the conductive fiber, the conductive polymer and the water soluble binder resin are each the same amount used in the manufacturing method (A).

As a mold-releasing substrate employed in the above-described manufacturing method (C) of the transparent electrode of the present invention, appropriately listed are resin substrates and resin films. The above resins are not particularly limited, and it is possible to appropriately select any of those known in the art. For example, appropriately employed are substrates and films, each of which is structured of a single layer or a plurality of layers composed of synthetic resins such as a polyethylene terephthalate resin, a vinyl chloride resin, an acrylic resin, a polycarbonate resin, a polyimide resin, a polyethylene resin, or a polypropylene resin. Further employed may be a glass substrate and a metal substrate. Further, if desired, the surface (the mold-releasing surface) of mold-releasing substrates may be subjected to surface treatment via application of a releasing agent such as a silicone resin, a fluororesin, or a wax.

Since a mold-releasing substrate surface affects the surface smoothness of the surface after transferring a transparent conductive layer, it is preferable that the mold-releasing substrate has high smoothness (Ry and Ra), it is preferable to have Ry≦50 nm, it is more preferable to have Ry≦40 nm, and it is still more preferable to have Ry≦30 nm. Moreover, it is preferable to have Ra≦5 nm, it is more preferable to have Ra≦3 nm, and it is still more preferable to have Ra≦1 nm.

The following processes can be cited, for example as a concrete way of forming the transparent conductive layer excellent in the surface smoothness containing a conductive fiber and a conductive material on a transparent substrate.

On a mold-releasing surface of a mold-releasing substrate, a conductive network structure made of conductive fibers is formed by applying (or printing) a dispersion liquid containing a conductive fiber followed by drying. Subsequently, a dispersion liquid of a conductive material is applied (or printed) on the network structure of the conductive fibers, thereby the space between the network structures of the conductive fibers on the substrate surface is filled with the conductive material, and a transparent conductive layer containing the conductive fiber and the conductive material is formed. Subsequently, on this transparent conductive layer or on another transparent substrate, an adhesive layer is provided and both the transparent conductive layer and the adhesive layer are adhered. After curing the adhesive layer, the transparent conductive layer is transferred to the transparent substrate by peeling off the mold-releasing substrate.

According to this process, since the network structure of a conductive fiber is arranged in three dimensions in a conductive material layer, the contact area of the conductive fiber and the conductive material can be increased, the auxiliary electrode function of the conductive fiber can fully be utilized, and the transparent conductive layer excellent in conductivity can be formed.

In the above-mentioned process, it is effective as a way of increasing the conductivity of the network structure of the conductive fiber to perform a calendar process and heat treatment so as to improve the adhesion between the conductive fibers after applying and drying the conductive fiber, or to perform plasma treatment so as to reduce the contact resistance between the conductive fibers. Moreover, in the above-mentioned process, hydrophilization treatment such as corona discharge (plasma) treatment may be beforehand carried out onto the mold-releasing surface of the mold-releasing substrate.

In the above-mentioned process, the adhesive layer may be prepared on the mold-releasing substrate side, and it may be prepared in the transparent substrate side. As an adhesive agent used for the adhesive layer, it will not be limited in particular, as long as it is transparent in the visible region, and as long as it has transfer ability. It may be a thermosetting resin or thermo plastic resin.

Although a thermosetting resin, a ultraviolet curing resin, an electron beam curing resin are cited as examples of a curable resin, among these curable resins, since the appliance for resin curing is simple, and it excels in working property, it is preferable to use a ultraviolet curing resin. A ultraviolet curing resin is a resin which is hardened through a cross linkage reaction by UV irradiation, and the ingredient containing the monomer which has an ethylenic unsaturated double bond is used preferably. For example, an acrylic urethane resin, a polyester-acrylates resin, an epoxy acrylate resin and a polyacrylate resin are cited. In the present invention, it is preferable to use a ultraviolet curing resin of an acrylic system and an acrylic urethane system as a main ingredient of a binder.

An acrylic urethane resin can be easily obtained by allowing to react an acryrate monomer having a hydroxyl group with the product generally acquired by the reaction of a polyester polyol with an isocyanate monomer or a prepolymer. Examples of the acryrate monomer having a hydroxyl group include: 2-hydroxyethyl acrylate, 2-hydroxyethyl methacrylate (hereafter, in the term “acrylate” it includes both “acrylate” and “methacrylate”) and 2-hydroxypropyl acrylate. For example, the compound described in JP-A No. 59-151110 can be used. More specifically, the mixture of 100 part of UNIDIC 17-806 (made by DIC Co., Ltd.) and 1 part of CORONATE L (made by Nippon Polyurethane Industry Co., Ltd.) is used preferably.

As an example of ultraviolet curing polyester-acrylates resin, it can be cited a compound which is formed easily by the reaction of a polyester polyol with a monomer such as 2-hydroxyethyl acrylate or 2-hydroxy acrylate. The compound described in JP-A No. 59-151112 can be used.

As an example of a ultraviolet curing epoxy acrylate resin, it can be cited a compound which can be produced by the following process: epoxy acrylate is made into an oligomer, then a reactive diluent and a photoinitiator are added and allowed to react with the oligomer to obtain the target compound. The compound described in JP-A No. 1-105738 can be used.

Examples of a ultraviolet curing polyol polyacrylate resin include: trimethylolpropane triacrylate, ditrimethylolpropane tetraacrylate, pentaerythritol triacrylate, pentaerythritol tetraacrylate, dipentaerythritol hexaacrylate and alkyl modified dipentaerythritol pentaacrylate.

As a resin monomer, conventional monomers having an unsaturated double bond can be cited, and examples of such monomer include: methyl acrylate, ethyl acrylate, butyl acrylate, benzyl acrylate, a cyclohexyl acrylate, vinyl acetate and styrene. Examples of monomers having two or more unsaturated double bonds are: ethylene glycol diacrylate, propylene glycol diacrylate, divinylbenzne, 1,4-cyclohexane diacrylate, 1,4-cyclohexyldimethyladiacrylate, trimethylolpropane triacrylate and pentaerythritol tetraacrylate.

Among these, a preferable compound to be used as a main ingredient of a binder is an acrylic actinic-ray curable resin. Examples of this include: 1,4-cyclohexane diacrylate, pentaerythritol tetra(meth)acrylate, pentaerythritol tri(meth)acrylate, trimethylolpropane (meth)acrylate, trimethylolethane (meth)acrylate, dipentaerythritol tetra(meth)acrylate, dipentaerythritol penta(meth)acrylate, dipentaerythritol hexa(meth)acrylate, 1,2,3-cyclohexanetetra methacrylate, polyurethane polyacrylate and polyester polyacrylate.

As a photoinitiator for these ultraviolet curing resins, specifically cited compounds are: benzoin, acetophenone, benzophenone, hydroxybenzophenone, Michler's ketone, α-amyloxim ester, thioxanthone and their derivatives. The photoinitiator may be used with a photosensitizer. The above-mentioned photoinitiator can also be used as a photosensitizer. Moreover, sensitizers such as n-butylamine, triethylamine and tri-n-butylphosphine can be used when the photoinitiator of an epoxy acrylate is employed. The amount of the photoinitiator or the amount of the photosensitizer used for a ultraviolet curing resin composition is 0.1-15 weight parts with respect to 100 weight parts of the composition, and it is preferably 1-10 weight parts.

After pasting together the mold-releasing substrate on which the transparent conductive layer was formed with the transparent substrate material, the adhesive agent is cured by irradiating with a UV light, then a transparent conductive layer can be transferred to the transparent substrate side by peeling off the mold-releasing substrate from the cured adhesive agent. Here, the adhesion way is not restricted in particular. Although a sheet press machine or a roll press machine can be used for adhesion, it is preferable to use a roll press machine. A roll press machine is preferably used since it can give pressure uniformly and its manufacturing efficiency is better than a sheet press machine.

### [Patterning Method]

The transparent conductive layer concerning the present invention can be patterned. There is no restriction in particular to the method and process of patterning, and a well-known approach can be applied suitably. For example, after forming the patterned transparent conductive layer on the mold-releasing surface, then by transferring the transparent conductive layer onto a transparent substrate, the patterned transparent electrode can be obtained. Specifically, the following methods can be preferably used.
(i) The method in which a transparent conductive layer of the present invention is directly built in a pattern by using a printing method on a mold-releasing substrate.
(ii) The method in which a transparent conductive layer of the present invention is uniformly built on a mold-releasing substrate followed by carrying out pattering by a conventional photolithographic process.
(iii) The method in which a transparent conductive layer of the present invention is uniformly built on a mold-releasing substrate using a conductive material containing a UV curable resin followed by carrying out pattering in the same manner as a photolithographic process.
(iv) The method in which a transparent conductive layer of the present invention is uniformly built a negative pattern using a photoresist which has been provided on a mold-releasing substrate, then patterning using a lift off method is carried out.

By using any one of the above-mentioned methods, the patterned transparent electrode of the present invention can be formed by transferring the patterned transparent conductive layer produced on the mold-releasing substrate onto a transparent substrate.

### [Organic Electroluminescence Element]

The organic electroluminescence element of the present invention is characterized in that it contains the transparent electrode of the present invention. The organic electroluminescence element of the present invention employs the transparent electrode of the present invention as an anode. About an organic light emitting layer and a cathode, arbitrary materials and compositions generally used for an organic electroluminescence element can be used.

Examples of a layer structure of the organic electroluminescence element can be cited as follows.
(i) anode/organic light emitting layer/cathode
(ii) anode/positive hole transport layer/organic light emitting layer/electron transport layer/cathode
(iii) anode/positive hole injection layer/positive hole transport layer/organic light emitting layer/electron transport layer/cathode
(iv) anode/positive hole injection layer/organic light emitting layer/electron transport layer/electron injection layer/cathode
(v) anode/positive hole injection layer/organic light emitting layer/electron injection layer/cathode

Examples of a light emitting material or a doping material used in an organic light emitting layer of the present invention include: anthracene, naphthalene, pyrene, a tetracene, coronene, perylene, phthaloperylene, naphthaloperylene, diphenylbutadiene, tetraphenylbutadiene, coumarin, oxadiazole, bisbenzoxazoline, bisstyryl, cyclopentadiene, quinoline metal complex, tris(8-hydroxyquinolinate)aluminium complex, tris(4-methyl-8-quinolinate) aluminium complex, tris(5-phenyl-8-quinolinate) aluminium complex, aminoquinoline metal complex, benzoquinoline metal complex, tri-(p-terphenyl-4-yl)amine, 1-aryl-2,5-di(2-thienyl)pyrrole derivative, pyrane, quinacridone, rubrene, distilbene derivative, distilarylene derivative, fluorescent dye, rare earth metal complex and phosphorescence emitting material. However, the present invention is not limited to them. It is preferable that the light emitting material selected from theses compound is contained in an amount of 90 to 99.5 weight % and that the doping material is contained in an amount of 0.5 to 10 weight %. The organic light emitting layer is produced with conventionally known methods using the above-described compounds, and an evaporation deposition method, a coating method and a transfer method are cited as examples. The thickness of the organic light emitting layer is preferably from 0.5 to 500 nm, and it is more preferably from 0.5 to 200 nm.

The organic electroluminescence element of the present invention can be used for a self emitting display, a backlight for a liquid crystal display and illumination. Since the organic electroluminescence element of the present invention can emit light uniformly, it is preferable to use for

### [Appropriate Application]

The transparent electrode of the present invention has high conductivity and transparency, and it can be used conveniently in the field of various optoelectronic devices such as liquid crystal display elements, organic electroluminescence elements, inorganic electroluminescence elements, electronic papers, organic solar cells, and inorganic solar cells; electromagnetic wave shields and touch panels. Among them, it can be suitably used for an organic electroluminescence element which is severely required the surface smoothness of the surface of a transparent electrode or for a transparent electrode of an organic thin film solar battery element.

### EXAMPLES

The present invention is described below with reference to examples, but the present invention is not limited to these. In examples, “part” or “%” may be used. Unless particularly mentioned, each respectively represents “weight part” or “weight %”.

### [Synthesis of Water Soluble Binder Resin]

Hereafter, synthetic examples of a water soluble binder resin of the present invention and a comparative water soluble binder resin will be described.

### <<Synthesis of Water Soluble Binder Resins 1 to 5 of the Present Invention Using Living Polymerization Method (ATP: Atom Transfer Radical Polymerization)>>

First, the following Initiator 1 was prepared.

### Synthesis of Initiator 1 (Methoxy Capped oligo(ethylene glycol) 2-bromoisobutyrylate: Synthetic Route

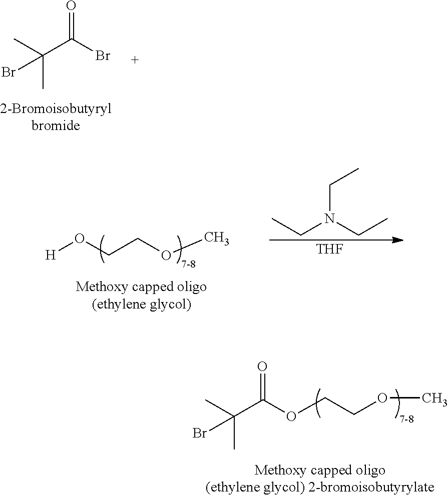

In a 50 ml three necked flask were placed 7.3 g (35 mmol) of 2-bromoisobutyryl bromide, 2.48 g (35 mmol) of triethylamine and 20 ml of THF. The inner temperature of the solution was kept to be 0° C. with an ice bath. Into the solution was dropwise added 10 g (23 mmol) of oligo(ethylene glycol) (the number of ethylene glycol being 7 to 8, made by Laporte Specialties Co., Ltd.) as 33% of THF solution in an amount of 30 ml. After stirring the solution for 30 minutes, the temperature of the solution was raised to room temperature, and further the solution was stirred for 4 hours. THF was removed under reduced pressure with a rotary evaporator. The residue was dissolved in ethyl ether and transferred into a separation funnel. Water was added in the separation funnel to wash the ether layer. After repeating this process 3 times, the ether layer was dried with MgSO₄. Ether was removed under reduced pressure with a rotary evaporator to obtain 8.2 g (yield: 73%) of Initiator 1.

### Synthetic Example 1

### Synthesis of Water Soluble Binder Resin 1: poly(2-hydroxyethyl methacrylate) (Present Invention)

Into a Schlenk flask were placed 500 mg (1.02 mmol) of Initiator 1, 2.6 g (20 mmol) of 2-hydroxyethyl methacrylate (made by Tokyo Kasei Co., Ltd.) and 5 ml of a water-methanol mixed solvent (50:50 (v/v %)). The Schlenk flask was immersed in liquid nitrogen under a reduced pressure for 10 minutes. The Schlenk flask was taken out from liquid nitrogen. After 5 minutes, nitrogen gas substitution was carried out. This operation was repeated three times. Then, 400 mg (2.56 mmol) of bipyridine and 147 mg (1.02 mmol) of CuBr were added into the Schlenk flask under nitrogen and stirred at 20° C. After 30 minutes, the reaction solution was dropped on a Kiriyama Rohto (diameter of 4 cm) provided with a filter paper and silica and the reaction solution was recovered. The solvent was removed under a reduced pressure with a rotary evaporator. The residue was dried under a reduced pressure at 50° C. for 3 hours to yield 2.60 g (yield: 84%) of Water soluble binder resin 1. The produced Water soluble binder resin 1 exhibited the number average molecular weight of 13,100, molecular weight distribution of 1.17, and the content of the components of the number average molecular weight of less than 1,000 was 0 weight %.

The structure and the number average molecular weight of PHEA-1 were respectively measured with ¹H-NMR (400 MHz, made by JEOL Ltd.) and GPC (Waters 2695, made by Waters Co., Ltd.).

### <GPC Measurement Conditions>

Apparatus: Wagers 2695 (Separations Module)
Detector: Waters 2414 (Refractive Index Detector)
Column: Shodex Asahipak GF-7M HQ
Eluant: Dimethylformamide (20 mM LiBr)
Flow rate: 1.0 ml/min
Temperature: 40 degrees C.

### Synthetic Example 2

### Synthesis of Water soluble binder resin 2: poly(2-hydroxyethyl acrylate) (Present Invention)

Water soluble binder resin 2 was produced in the same manner as preparation of Water soluble binder resin 1 in Synthetic example 1, except that 4.64 g (40 mmol) of 2-hydroxyethyl acrylate was used as a monomer instead of 2-hydroxyethyl methacrylate. It was produced 4.57 g (yield: 89%) of Water soluble binder resin 2. The produced Water soluble binder resin 2 exhibited the number average molecular weight of 26,200, molecular weight distribution of 1.15, and the content of the components of the number average molecular weight of less than 1,000 was 0 weight %.

### Synthetic Example 3

### Synthesis of Water Soluble Binder Resin 3: poly(3-hydroxypropyl acrylate) (Present Invention)

Water soluble binder resin 3 was produced in the same manner as preparation of Water soluble binder resin 1 in Synthetic example 1, except that 3.90 g (30 mmol) of 3-hydroxypropyl acrylate was used as a monomer instead of 2-hydroxyethyl methacrylate. It was produced 3.56 g (yield: 81%) of Water soluble binder resin 3. The produced Water soluble binder resin 3 exhibited the number average molecular weight of 18,700, molecular weight distribution of 1.19, and the content of the components of the number average molecular weight of less than 1,000 was 0 weight %.

### Synthetic Example 4

### Synthesis of Water Soluble Binder Resin 4: poly(2-(2-hydroxyethoxy)ethyl acrylate) (Present Invention)

Water soluble binder resin 4 was produced in the same manner as preparation of Water soluble binder resin 1 in Synthetic example 1, except that 5.22 g (30 mmol) of 2-(2-hydroxyethoxy)ethyl acrylate was used as a monomer instead of 2-hydroxyethyl methacrylate. It was produced 4.69 g (yield: 82%) of Water soluble binder resin 4. The produced Water soluble binder resin 4 exhibited the number average molecular weight of 19,800, molecular weight distribution of 1.21, and the content of the components of the number average molecular weight of less than 1,000 was 0 weight %.

### Synthetic Example 5

### Synthesis of Water Soluble Binder Resin 5: poly(2,3-dihydroxypropyl methacrylate) (Present Invention)

Water soluble binder resin 5 was produced in the same manner as preparation of Water soluble binder resin 1 in Synthetic example 1, except that 6.41 g (40 mmol) of 2,3-dihydroxypropyl methacrylate was used as a monomer instead of 2-hydroxyethyl methacrylate. It was produced 5.45 g (yield: 85%) of Water soluble binder resin 5. The produced Water soluble binder resin 5 exhibited the number average molecular weight of 18,700, molecular weight distribution of 1.16, and the content of the components of the number average molecular weight of less than 1,000 was 0 weight %.

<<Synthesis of Water Soluble Binder Resin by Radical Polymerization with AIBN>>

### Synthetic Example 6

### Synthesis of Water Soluble Binder Resin A: poly(2-hydroxyethyl acrylate) (Comparative Sample)

In a 300 ml three necked flask was placed 200 ml of THF and it was refluxed for 10 minutes. Then it was cooled to room temperature under nitrogen. In the flask were added 10.0 g (86 mmol) of 2-hydroxyethyl acrylate and 2.8 g (17.1 mmol) of AIBN and they were heated to reflux for 5 hours. After the reaction solution was cooled to room temperature, it was dropped in 2,000 ml of MEK and the solution was stirred for one hour. After MEK was removed by decantation, the residue was washed three times with 100 ml of MEK. The obtained polymer was dissolved in THF and the solution was transferred to a 100 ml flask. THF was removed under reduced pressure with a rotary evaporator. The residue was dried under a reduced pressure at 50° C. for 3 hours to obtain 9.0 g (yield: 90%) of Water soluble binder resin A (comparative sample). The produced Water soluble binder resin A exhibited the number average molecular weight of 22,100, molecular weight distribution of 1.42, and the content of the components of the number average molecular weight of less than 1,000 was 11 weight %.

### Synthetic Example 7

### Preparation of Water Soluble Binder Resin 6: Reprecipitation of Water Soluble Binder Resin A (poly(2-hydroxyethyl acrylate) (Present Invention)

2.0 g of Water soluble binder resin A produced in Synthetic example 6 was dissolved in 10 ml of THF. This solution was dropped in 300 ml of a mixed solvent of MEK and acetone (80:20 (v/v %)) and the mixture was stirred for one hour. After the solvent was removed by decantation, the residue was washed three times with 50 ml of MEK. The obtained polymer was dissolved in THF and the solution was transferred to a 50 ml flask. THF was removed under reduced pressure with a rotary evaporator. The residue was dried under a reduced pressure at 50° C. for 3 hours to obtain 1.20 g (recovery yield: 60%) of Water soluble binder resin 6. The produced Water soluble binder resin 6 exhibited the number average molecular weight of 27,600, molecular weight distribution of 1.22, and the content of the components of the number average molecular weight of less than 1,000 was 2 weight %.

### Synthetic Example 8

Preparation of Water Soluble Binder Resin 7: Reprecipitation of Water Soluble Binder Resin A (poly(2-hydroxyethyl acrylate) (Present Invention)

Water soluble binder resin 7 was produced in the same manner as preparation described in Synthetic example 7, except that 200 ml of a mixed solvent of MEK and acetone (80:20 (v/v %)) was used for dropping the solution of Water soluble binder resin A. Thus it was obtained 1.47 g (recovery yield: 71%) of Water soluble binder resin 7. The produced Water soluble binder resin 7 exhibited the number average molecular weight of 23,200, molecular weight distribution of 1.31, and the content of the components of the number average molecular weight of less than 1,000 was 5 weight %.

### Synthetic Example 9

### Preparation of Water Soluble Binder Resin B: Reprecipitated of Water Soluble Binder Resin A (poly(2-hydroxyethyl acrylate) (Present Invention)

Water soluble binder resin B was produced in the same manner as preparation described in Synthetic example 7, except that 120 ml of a mixed solvent of MEK and acetone (80:20 (v/v %)) was used for dropping the solution of Water soluble binder resin A. Thus it was obtained 1.55 g (recovery yield: 78%) of Water soluble binder resin B. The produced Water soluble binder resin B exhibited the number average molecular weight of 22,900, molecular weight distribution of 1.35, and the content of the components of the number average molecular weight of less than 1,000 was 7 weight %.

### <<Preparation of Water Soluble Binder Resin by Reprecipitation of a Commercially Available Water Soluble Binder Resin>>

### Synthetic Example 10

### Preparation of Water Soluble Binder Resin 8: Reprecipitation of Commercially Available Poly(vinyl pyrrolidone) (Present Invention)

2.0 g of Poly(vinyl pyrrolidone) (made by Polyscience Inc.) was dissolved in 40 ml of water. This solution was dropped in 300 ml of a mixed solvent of MEK and acetone (80:20 (v/v %)) and the mixture was stirred for one hour. The solution was filtered with Nutsche and filter paper. The solid portion was transferred to a Petri dish and it was dried under a reduced pressure for 3 hours. Thus it was obtained 1.10 g (recovery yield: 44%) of Water soluble binder resin 8. The produced Water soluble binder resin 8 exhibited the number average molecular weight of 12,700, and the content of the components of the number average molecular weight of less than 1,000 was 4 weight %.

### Synthetic Example 11

Preparation of Water Soluble Binder Resin 9: Reprecipitation of Commercially Available Poly(vinyl pyrrolidone) (Present Invention)

Water soluble binder resin 9 was produced in the same manner as preparation of Water soluble binder resin 8 in Synthetic example 10, except that poly(vinyl alcohol) (made by Polyscience Inc.) was used instead of poly(vinyl pyrrolidone) (made by Polyscience Inc.). Thus it was obtained 0.54 g (recovery yield: 27%) of Water soluble binder resin 9. The produced Water soluble binder resin 9 exhibited the number average molecular weight of 22,100, and the content of the components of the number average molecular weight ofless than 1,000 was 3 weight %.

### Synthetic Example 12

### Preparation of Water Soluble Binder Resin 10: Reprecipitation of Commercially Available Hydroxypropyl Methyl Cellulose (HPMC) 60SH (Present Invention)

Water soluble binder resin 10 was produced in the same manner as preparation of Water soluble binder resin 8 in Synthetic example 10, except that hydroxypropyl methyl cellulose (HPMC) 60SH (made by Shin-Etsu Chemical Co., Ltd) was used instead of poly(vinyl pyrrolidone) (made by Polyscience Inc.). Thus it was obtained 0.68 g (recovery yield: 34%) of Water soluble binder resin 10.

The produced Water soluble binder resin 10 exhibited the number average molecular weight of 43,700, and the content of the components of the number average molecular weight of less than 1,000 was 3 weight %.

### [Preparation of Silver Nanowire]

As metal particles, there were prepared silver nanowires having an average minor axis of 75 nm and an average length of 35 pm using poly(vinyl pyrrolidone) K30 (molecular weight of 50,000, made by ISP Co., Ltd.) with reference to the method described in Adv. Mater., 2002, 14, 833-837. The prepared silver nanowires were filtered using a ultrafiltration membrane followed by washing with water. Then, the silver nanowires were re-dispersed in an aqueous solution of hydroxypropyl methyl cellulose (HPMC) BOSH (made by Shin-Etsu Chemical Co., Ltd), wherein hydroxypropyl methyl cellulose (HPMC) BOSH was added in an amount of 25 weight % with respect to silver.

### Example 1

### Preparation of Transparent Electrode TC-101: Present Invention

On a polyethylene terephthalate film support (Cosmoshine A4100™, made by Toyobo Co., Ltd.) which had been performed adhesion assisting treatment, was applied the water dispersion liquid of the prepared silver nanowires using a spin coater so that the coated amount of the silver nanowires became 0.05 g/m², then it was dried. Then, after performing a calendar process to the coated layer of the silver nanowires, a stripe-like transparent pattern electrode TCF-1 with an electrode pattern width of 10 mm and a patter space of 10 mm was produced with a well-known photolithography method.

Subsequently, to Conductive polymer P-1 (Baytron PH510, made by H. C. Starck Co., Ltd., 1.3% of solid content), which is a dispersion liquid of a mixture of PEDOT and PSS (polystyrene sulfonate) (mixing ratio of 1:2.5), was added Water soluble binder resin 1 of the present invention so that the amount of the Water soluble binder resin 1 became 30 weight % with respect to the solid content of the aforesaid Conductive polymer P-1. Further, a melamine resin BECKAMINE M-3 (made by DIC Corporation) and a cross linkage accelerator CATALYST ACX (made by DIC Co., Ltd.) were added so that that the amount of each component became 10 weight% and 1 weight % with respect to the solid content of the Conductive polymer P-1, respectively. Transparent electrode TC-101 was produced by applying thus prepared coating solution with a spin coater on the transparent pattern electrode TCF-1 so that the dried coating thickness became 300 nm, and dried at 120° C. for 30 minutes

### Preparation of Transparent Electrodes TC-102 to TC-112: Present Invention

Transparent electrodes TC-102 to TC-112 were produced in the same manner as preparation of transparent electrode TC-101, except that the Water soluble binder resin 1 of the present invention was replaced with Water soluble binder resins 2 to 10, A and B as are shown in Table 1.

### Preparation of Transparent Electrodes TC-113: Comparative Sample

Transparent electrodes TC-113 was produced in the same manner as preparation of transparent electrode TC-101, except that the Water soluble binder resin 1 of the present invention was not added.

### Preparation of Transparent Electrodes TC-114: Comparative Sample

Transparent electrodes TC-114 was produced in the same manner as preparation of transparent electrode TC-101, except that the Water soluble binder resin 1 of the present invention, a melamine resin BECKAMINE M-3 (made by DIC Co., Ltd.) and a cross linkage accelerator CATALYST ACX (made by DIC Co., Ltd.) were replaced with Polyurethane resin 1 (water insoluble binder resin Byron UR-3220: 30% polyurethane MEK solution, made by Toyobo Co., Ltd.) The added amount of Polyurethane resin 1 was 30 weight % with respect to the solid content of the conductive polymer.

### Preparation of Transparent Electrodes TC-115 to TC-122: The Present Invention

Transparent electrodes TC-115 to TC-122 were produced in the same manner as preparation of transparent electrodes TC-101 and TC-106 to TC-112, except that Conductive polymer P-1 (Clevios PH510, made by H. C. Starck Co., Ltd., 1.3% of solid content), which is a dispersion liquid of a mixture of PEDOT and PSS (polystyrene sulfonate) (mixing ratio of 1:2.5) was replaced with Conductive polymer P-2 (Polyaniline M, made by TA Chemical Co., Ltd., solid content of 6.0%) which had been adjusted to have a solid content of 3.0% with pure water.

### Preparation of Transparent Electrodes TC-123: Comparative Sample

Transparent electrodes TC-123 was produced in the same manner as preparation of transparent electrode TC-115, except that the Water soluble binder resin 1 of the present invention was not added.

### (Evaluation)

The total optical transmittance, surface resistivity, and surface smoothness (Ra, Ry) were measured using the following methods for transparent electrodes TC-101 to TC-123 produced as mentioned above. Moreover, in order to evaluate the stability of a transparent electrode, there were measured the total optical transmittance, surface resistivity, and surface smoothness (Ra, Ry) of the transparent electrode sample after subjected to the forced aging test accomplished by placing for three days under the ambient of 80° C. and 90% RH. The compositions of the prepared samples and the evaluation results are shown in Table 1.

### [Total Optical Transmittance]

Based on JIS K 7361-1:1997, it was measured using haze meter HGM-2B made by Suga Test Instruments Co., Ltd.

### [Surface Resistivity]

Based on JIS K 7194: 1994, it was measured using Mitsubishi Chemical Rolester GP (MCP-T610 type).

[Surface smoothness (Ra, Ry)]

An atomic force microscope (AFM) (SPI3800N probe station and SPA400 multifunctional-capability type module made by Seiko Instruments Co., Ltd.) was used. The sample cut off in a square having a side of about 1 cm was used and the measurement was carried out with the above-mentioned method based on the surface smoothness measurement specified by JIS B601 (1994).

TABLE 1

| | | | | Stability | | | | | | | | |
|---|---|---|---|---|---|---|---|---|---|---|---|---|
| | | Water soluble | | | | | | After subjected to forced aging test (80° C., | | | | |
| Trans- | | binder resin | | Before subjected to forced aging test | | | | 90% RH, 3 days) | | | | |
| parent | Conduc- | | (*) Ratio | Total optical | Surface | | | Total optical | Surface | | | |
| electrode | tive | | (weight | trans- | resistivity | Ry | Ra | trans- | resistivity | Ry | Ra | Re- |
| No. | polymer | Kind | %) | mittance | (Ω/□) | (ran) | (nm) | mittance | (Ω/□) | (nm) | (nm) | marks |
| TC-101 | P-1 | 1 | 0 | 84% | 10 | 23 | 3 | 84% | 14 | 35 | 6 | Inv. |
| TC-102 | P-1 | 2 | 0 | 85% | 10 | 22 | 2 | 83% | 12 | 29 | 5 | Inv. |
| TC-103 | P-1 | 3 | 0 | 84% | 10 | 25 | 5 | 83% | 15 | 33 | 8 | Inv. |
| TC-104 | P-1 | 4 | 0 | 83% | 10 | 24 | 3 | 82% | 13 | 34 | 8 | Inv. |
| TC-105 | P-1 | 5 | 0 | 84% | 10 | 24 | 4 | 80% | 16 | 32 | 6 | Inv. |
| TC-106 | P-1 | 6 | 2 | 85% | 10 | 23 | 3 | 80% | 13 | 42 | 7 | Inv. |
| TC-107 | P-1 | 9 | 3 | 83% | 20 | 24 | 4 | 82% | 21 | 47 | 6 | Inv. |
| TC-108 | P-1 | 10 | 3 | 84% | 20 | 23 | 3 | 84% | 22 | 45 | 5 | Inv. |
| TC-109 | P-1 | 8 | 4 | 84% | 20 | 21 | 4 | 84% | 25 | 50 | 5 | Inv. |
| TC-110 | P-1 | 7 | 5 | 84% | 20 | 24 | 3 | 82% | 23 | 37 | 8 | Inv. |
| TC-111 | P-1 | B | 7 | 83% | 20 | 25 | 5 | 78% | 51 | 63 | 21 | Comp. |
| TC-112 | P-1 | A | 11 | 85% | 10 | 29 | 5 | 77% | 64 | 91 | 29 | Comp. |
| TC-113 | P-1 | — | — | 75% | 10 | 27 | 3 | 67% | 55 | 254 | 57 | Comp. |
| TC-114 | P-1 | Polyurethane | — | 87% | 30 | 43 | 13 | 78% | 103 | 436 | 83 | Comp. |
| | | resin 1 | | | | | | | | | | |
| TC-115 | P-2 | 1 | 0 | 82% | 10 | 27 | 4 | 80% | 19 | 44 | 9 | Inv. |
| TC-116 | P-2 | 6 | 2 | 82% | 20 | 29 | 5 | 82% | 29 | 48 | 8 | Inv. |
| TC-117 | P-2 | 9 | 3 | 82% | 20 | 28 | 5 | 82% | 27 | 50 | 7 | Inv. |
| TC-118 | P-2 | 10 | 3 | 81% | 20 | 28 | 3 | 82% | 26 | 47 | 8 | Inv. |
| TC-119 | P-2 | 8 | 4 | 82% | 20 | 30 | 5 | 82% | 26 | 43 | 7 | Inv. |
| TC-120 | P-2 | 7 | 5 | 82% | 20 | 27 | 4 | 80% | 25 | 41 | 9 | Inv. |
| TC-121 | P-2 | B | 7 | 81% | 20 | 30 | 5 | 76% | 57 | 71 | 24 | Comp. |
| TC-122 | P-2 | A | 11 | 83% | 10 | 34 | 7 | 72% | 88 | 119 | 36 | Comp. |
| TC-123 | P-2 | — | — | 73% | 10 | 36 | 4 | 67% | 61 | 337 | 65 | Comp. |

Inv.: Present invention,
Comp.: Comparison
(*) Ratio: a ratio of a component having the number average molecular weight of less than 1,000 incorporated in the water soluble binder resin
[Remarks on the compounds listed in Table 1]
(Water insoluble binder resin)
Polyurethane resin 1: Byron UR-3220 (30% polyurethane MEK solution, made by Toyobo Co., Ltd)
(Conductive polymer):
P-1: Baytron PH510 which is a dispersion liquid of a mixture of PEDOT and PSS (Polystyrene Sulfonate) with a mixing ratio of 1:2.5 (made by C. H. Starck, solid content; 1.3%)
P-2: Poly aniline M (Poly Aniline, made by TA Chemical Co. Ltd., solid content; 6.0%)

From the results shown in Table 1, it was revealed that transparent electrodes TC-111 to TC-114, and TC-121 to TC-123 (comparison) exhibited inferior surface resistivity and surface smoothness after subjected to the forced aging test of placing for three days under the ambient of 80° C. and 90% RH. Transparent electrodes TC-111 to TC-114, and TC-121 to TC-123 were prepared by any one of the following conditions: (i) incorporating only a conductive polymer on the silver nanowires; (ii) incorporating the water soluble binder resin which contains a substance having the number average molecular weight of less than 1,000 in an amount of 5 weight % or more; (iii) incorporating a polyurethane resin instead of the water soluble resin of the present invention.

On the other hand, it was shown that transparent electrode TC-101 to TC-110, and TC-115 to TC-100 of the present invention exhibited much more stable surface resistivity and surface smoothness.

### Example 2

### Preparation of Transparent Electrode TC-201: Present Invention

Conductive polymer P-1 (Baytron PH510) was condensed with a rotary evaporator to become the solid content of 13%. (Baytron PH510 is a dispersion liquid of a mixture of PEDOT and PSS (polystyrene sulfonate) (mixing ratio of 1:2.5), made made by H. C. Starck Co., Ltd., 1.3% of solid content). Thus condensed Conductive polymer P-1 was taken in an amount of 3 times of the weight of the prepared silver nanowires. Then, there was added Water soluble binder resin 1 of the present invention in an amount of 50 weight % of the amount of the Conductive polymer P-1. Further, there were added a melamine resin BECKAMINE M-3 (made by DIC Co., Ltd.) and a cross linkage accelerator CATALYST ACX (made by DIC Co., Ltd.) so that that the amount of each component became 10 weight % and 1 weight %, respectively with respect to the solid content of water soluble binder resin 1 of the present invention. Thus prepared coating solution was coated on a polyethylene terephthalate film support with a thickness of 100 μm which had been performed adhesion assisting treatment using a spin coater in an amount of the dried thickness to be 300 nm, and it was dried at 120° C. for 30 minutes.

### <Preparation of Metal Nanowire Removing Agent BF-1>

Composition of BF-1:

| | |
|---|---|
| Ethylenediaminetetraacetic acid Fe | 60 g |
| (III) ammonium salt | |
| Ethylenediaminetetraacetic acid | 2 g |
| Sodium metabisulfie | 15 g |
| Ammonium thiosulfate | 70 g |
| Maleic acid | 5 g |

Water was added to the above-described composition so that total volume became 1 L, then it was adjusted to pH 5.5 with an aqueous sulfuric acid solution or an aqueous ammonia solution. Thus, metal nanowire removing agent BF-1 was prepared.

Subsequently, after performing a calender treatment to the coating layer of silver nanowires, gravure printing was applied to it with Gravure coating apparatus K Printing Proofer (made by MATSUO SANGYO Co., Ltd.) in the following way. a plate having a reverse pattern of a 10 mm stripe shaped pattern was set to K Printing Proofer; the viscosity of the prepared metal nanowire removing agent BF-1 was suitably adjusted with CMC; and gravure printing was performed so that the coating thickness on the silver nanowire coating layer became 30 μm by controlling the printing times. After printing, it was left still for 1 minute, subsequently rinsing treatment by running water was performed, and transparent electrode TC-201 was produced.

### Preparation of Transparent Electrodes TC-202 to TC-212: Present Invention

Transparent electrodes TC-202 to TC-212 were produced in the same manner as preparation of transparent electrode TC-201, except that the Water soluble binder resin 1 of the present invention was replaced with Water soluble binder resins 2 to 10, A and B as are shown in Table 2.

### Preparation of Transparent Electrodes TC-213: Comparative Sample

Transparent electrodes TC-213 was produced in the same manner as preparation of transparent electrode TC-201, except that the Water soluble binder resin 1 of the present invention was not added.

### Preparation of Transparent Electrodes TC-214: Comparative Sample

Transparent electrodes TC-214 was produced in the same manner as preparation of transparent electrode TC-201, except that the Water soluble binder resin 1 of the present invention, a melamine resin BECKAMINE M-3 (made by DIC Co., Ltd.) and a cross linkage accelerator CATALYST ACX (made by DIC Co., Ltd.) were replaced with Polyurethane resin 1 (water insoluble binder resin Byron UR-3220: 30% polyurethane MEK solution, made by Toyobo Co., Ltd.) The added amount of Polyurethane resin 1 was 30 weight % with respect to the solid content of the conductive polymer.

### Preparation of Transparent Electrodes TC-215 to TC-222: The Present Invention

Transparent electrodes TC-215 to TC-222 were produced in the same manner as preparation of transparent electrodes TC-201 and TC-206 to TC-212, except that Conductive polymer P-1 (Clevios PH510, made by H. C. Starck Co., Ltd., 1.3% of solid content), which is a dispersion liquid of a mixture of PEDOT and PSS (polystyrene sulfonate) (mixing ratio of 1:2.5) was replaced with Conductive polymer P-2 (Polyaniline M, made by TA Chemical Co., Ltd., solid content of 6.0%).

### Preparation of Transparent Electrodes TC-223: Comparative Sample

Transparent electrodes TC-223 was produced in the same manner as preparation of transparent electrode TC-215, except that the Water soluble binder resin 1 of the present invention was not added.

### (Evaluation)

The total optical transmittance, surface resistivity, and surface smoothness (Ra, Ry) were measured in the same manner as describe in Example 1 for transparent electrodes TC-201 to TC-223 produced as mentioned above. Moreover, in order to evaluate the stability of a transparent electrode, there were measured the total optical transmittance, surface resistivity, and surface smoothness (Ra, Ry) of the transparent electrode sample after subjected to the forced aging test accomplished by placing for three days under the ambient of 80 ° C. and 90% RH.

The compositions of the prepared samples and the evaluation results are shown in Table 2.

TABLE 2

| | | | | Stability | | | | | | | | |
|---|---|---|---|---|---|---|---|---|---|---|---|---|
| | | Water soluble | | | | | | After subjected to forced aging test (80° C., | | | | |
| Trans- | | binder resin | | Before subjected to forced aging test | | | | 90% RH, 3 days) | | | | |
| parent | Conduc- | | (*) Ratio | Total optical | Surface | | | Total optical | Surface | | | |
| electrode | tive | | (weight | trans- | resistivity | Ry | Ra | trans- | resistivity | Ry | Ra | Re- |
| No. | polymer | Kind | %) | mittance | (Ω/□) | (nm) | (nm) | mittance | (Ω/□) | (nm) | (nm) | marks |
| TC-201 | P-1 | 1 | 0 | 85% | 10 | 22 | 3 | 85% | 15 | 35 | 8 | Inv. |
| TC-202 | P-1 | 2 | 0 | 85% | 10 | 19 | 3 | 84% | 13 | 31 | 6 | Inv. |
| TC-203 | P-1 | 3 | 0 | 83% | 10 | 24 | 4 | 83% | 13 | 33 | 7 | Inv. |
| TC-204 | P-1 | 4 | 0 | 84% | 10 | 24 | 4 | 82% | 11 | 33 | 9 | Inv. |
| TC-205 | P-1 | 5 | 0 | 84% | 10 | 24 | 5 | 82% | 14 | 34 | 8 | Inv. |
| TC-206 | P-1 | 6 | 2 | 85% | 10 | 21 | 3 | 83% | 15 | 35 | 4 | Inv. |
| TC-207 | P-1 | 9 | 3 | 83% | 20 | 24 | 5 | 82% | 29 | 32 | 7 | Inv. |
| TC-208 | P-1 | 10 | 3 | 84% | 20 | 24 | 4 | 84% | 26 | 34 | 5 | Inv. |
| TC-209 | P-1 | 8 | 4 | 83% | 20 | 23 | 4 | 83% | 27 | 32 | 6 | Inv. |
| TC-210 | P-1 | 7 | 5 | 83% | 20 | 22 | 4 | 82% | 24 | 38 | 8 | Inv. |
| TC-211 | P-1 | B | 7 | 83% | 20 | 26 | 6 | 76% | 53 | 77 | 22 | Comp. |
| TC-212 | P-1 | A | 11 | 84% | 10 | 27 | 5 | 75% | 72 | 101 | 25 | Comp. |
| TC-213 | P-1 | — | — | 74% | 10 | 29 | 6 | 69% | 61 | 278 | 53 | Comp. |
| TC-214 | P-1 | Polyurethane | — | 86% | 30 | 47 | 11 | 77% | 111 | 481 | 97 | Comp. |
| | | resin 1 | | | | | | | | | | |
| TC-215 | P-2 | 1 | 0 | 82% | 10 | 28 | 4 | 80% | 17 | 49 | 8 | Inv. |
| TC-216 | P-2 | 6 | 2 | 81% | 20 | 29 | 5 | 81% | 35 | 50 | 6 | Inv. |
| TC-217 | P-2 | 9 | 3 | 82% | 20 | 28 | 5 | 81% | 33 | 48 | 9 | Inv. |
| TC-218 | P-2 | 10 | 3 | 81% | 20 | 29 | 5 | 81% | 36 | 48 | 6 | Inv. |
| TC-219 | P-2 | 8 | 4 | 81% | 20 | 27 | 5 | 82% | 34 | 47 | 7 | Inv. |
| TC-220 | P-2 | 7 | 5 | 81% | 20 | 28 | 5 | 80% | 27 | 47 | 8 | Inv. |
| TC-221 | P-2 | B | 7 | 80% | 20 | 32 | 5 | 76% | 65 | 87 | 32 | Comp. |
| TC-222 | P-2 | A | 11 | 84% | 10 | 36 | 7 | 72% | 90 | 137 | 35 | Comp. |
| TC-223 | P-2 | — | — | 71% | 10 | 39 | 8 | 68% | 68 | 345 | 68 | Comp. |

Inv.: Present invention,
Comp.: Comparison
(*) Ratio: a ratio of a component having the number average molecular weight of less than 1,000 incorporated in the water soluble binder resin

From the results shown in Table 2, it was revealed that comparative transparent electrodes exhibited inferior surface resistivity and surface smoothness after subjected to the forced aging test of placing for three days under the ambient of 80° C. and 90% RH compared with transparent electrodes of the present invention.

Comparative transparent electrodes TC-213 and TC-223 were prepared by incorporating only a conductive polymer on the silver nanowires; transparent electrodes TC-211, TC-212, TC-221 and TC-222 were prepared by incorporating the water soluble binder resin which contains a substance having the number average molecular weight of less than 1,000 in an amount of 5 weight % or more; and transparent electrodes TC-214 was prepared by incorporating a polyurethane resin instead of the water soluble resin of the present invention. On the other hand, it was shown that transparent electrodes TC-201 to TC-210, and TC-215 to TC-220 of the present invention exhibited much more stable surface resistivity and surface smoothness.

### Example 3

### Preparation of Organic Electroluminescence Element (Organic EL Element)

Organic EL elements OEL-301 to OEL-323 were respectively produced in the following processes by using transparent electrodes TC-101 to TC-123 produced above as the 1^{st} a electrode.

### <Formation of Positive Hole Transporting Layer>

The coating solution for a positive hole transporting layer was prepared by dissolving 4,4′-bis[(N-(1-naphthyl)-N-phenylamino)]biphenyl (NPD) in 1,2-dichloroethane so that the content of NPD became 1 weight %. This coating solution was coated on the 1^{st} electrode with a spin coating apparatus followed by drying at 80° C. for 60 minutes to form a positive hole transporting layer having a thickness of 40 nm.

### <Formation of Light Emission Layer>

The coating solution for forming light emission layer was prepared by dissolving polyvinyl carbazole (PVK) as a host material, 1 weight % of a red dopant material Btp2Ir(acac), 2 weight % of a green dopant material Ir(ppy)3 and 3 weight % of a blue dopant material FIr(pic) (the indicated weight % was based on the weight of PVK) in 1,2-dichloroethane so that the total solids content of PVK and the three dopants became 1 weight %. This coating solution was coated with a spin coating apparatus followed by drying at 100° C. for 10 minutes to form a light emission layer having a thickness of 60 nm.

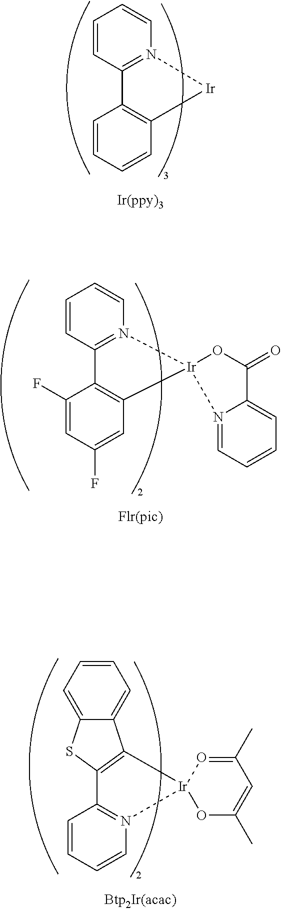

### <Formation of Electron Transporting Layer>

On the formed light emission layer, LiF was vapor-deposited as an electron transporting layer forming material under the vacuum of 5×10⁻⁴ Pa, and an electron transporting layer having a thickness of 0.5 nm was formed.

### <Formation of 2^{nd} Electrode>

On the formed electron transporting layer, aluminum was vapor-deposited as a 2^{nd} electrode forming material under the vacuum of 5×10⁻⁴ Pa, and a 2^{nd} electrode having a thickness of 100 nm was formed.

### <Formation of Sealing Film>

On the formed electron transporting layer, there was applied a flexible sealing member having a polyethylene terephthalate base on which was vapor-deposited Al₂O₃ with a thickness of 300 nm. In order to form external terminals for the 1^{st} electrode and the 2^{nd} electrode, the edge portion was eliminated and an adhesive agent was applied to the surrounding area of the 2^{nd} electrode. After sticking the flexible sealing member, the adhesive agent was cured with heating treatment.

### (Evaluation)

### [Uniformity of Luminescent Brightness]

Direct current voltage was impressed to the organic EL element to allow to emit light using Source Major Unit 2400 made by KEITHLEY Instrument Inc. For the organic EL elements OEL-301 to OEL-313 which were made to emit light with 200 cd/m², each luminescence uniformity was observed with a microscope at magnification of 50 times. Moreover, after the organic EL elements OEL-301 to OEL-323 were heated in an oven at 80° C. and 60% RH for 30 minutes, the aforesaid organic EL elements were left again at in an oven for 1 hour or more under the ambient of 23±3° C. and 55±3% RH. Then luminescence uniformity was observed similarly.

The evaluation criteria of luminescence uniformly are as follows.
A: the whole EL element emits light uniformly.
B: the whole EL element is emits light almost uniformly.
C: slight ununiformity of luminescence is observed
D: markedly ununiformity of luminescence is observed

The above-mentioned evaluation results are shown in Table 3.

TABLE 3

| | | Uniformity of luminescence | | |
|---|---|---|---|---|
| Organic EL | 1^{st} electrode | Before subjected | After subjected | |
| element | (Anode electrode) | to forced aging | to forced aging | Remarks |
| OEL-301 | TC-101 | A | A | Present invention |
| OEL-302 | TC-102 | A | A | Present invention |
| OEL-303 | TC-103 | B | B | Present invention |
| OEL-304 | TC-104 | A | A | Present invention |
| OEL-305 | TC-105 | A | B | Present invention |
| OEL-306 | TC-106 | A | A | Present invention |
| OEL-307 | TC-107 | B | B | Present invention |
| OEL-308 | TC-108 | A | B | Present invention |
| OEL-309 | TC-109 | B | B | Present invention |
| OEL-310 | TC-110 | A | B | Present invention |
| OEL-311 | TC-111 | B | C | Comparison |
| OEL-312 | TC-112 | A | C | Comparison |
| OEL-313 | TC-113 | B | C | Comparison |
| OEL-314 | TC-114 | B | D | Comparison |
| OEL-315 | TC-115 | A | A | Present invention |
| OEL-316 | TC-116 | A | B | Present invention |
| OEL-317 | TC-117 | A | B | Present invention |
| OEL-318 | TC-118 | B | B | Present invention |
| OEL-319 | TC-119 | B | B | Present invention |
| OEL-320 | TC-120 | B | B | Present invention |
| OEL-321 | TC-121 | B | C | Comparison |
| OEL-322 | TC-122 | B | D | Comparison |
| OEL-323 | TC-123 | B | D | Comparison |

It became clear from the evaluation results shown in Table 3 that the luminescence uniformity of organic EL elements OEL-311 to OEL-314, and OEL-321 to OEL-323 were remarkably deteriorated after subjected to heating at 80° C. and 60% RH for 30 minutes, while the luminescence uniformity of organic EL elements OEL-301 to OEL-310, and OEL-315 to OEL-320 of the present invention were highly stable even after subjected to heating.

### Example 4

### Preparation of Organic Electroluminescence Element (Organic EL Element)

Organic EL elements OEL-401 to OEL-423 were respectively prepared in the same manner as preparation process described in Example 3 by using transparent electrodes TC-201 to TC-223 produced above in Example 2 for the 1^{st} electrode.

Evaluation of organic EL elements were done in the same manner as evaluation described in Example 3.

The evaluation results are shown in Table 4.

TABLE 4

| | | Uniformity of luminescence | | |
|---|---|---|---|---|
| Organic EL | 1^{st} electrode | Before subjected | After subjected | |
| element | (Anode electrode) | to forced aging | to forced aging | Remarks |
| OEL-401 | TC-201 | A | B | Present invention |
| OEL-402 | TC-202 | A | A | Present invention |
| OEL-403 | TC-203 | B | B | Present invention |
| OEL-404 | TC-204 | A | B | Present invention |
| OEL-405 | TC-205 | B | B | Present invention |
| OEL-406 | TC-206 | A | B | Present invention |
| OEL-407 | TC-207 | A | A | Present invention |
| OEL-408 | TC-208 | B | B | Present invention |
| OEL-409 | TC-209 | B | B | Present invention |
| OEL-410 | TC-210 | A | B | Present invention |
| OEL-411 | TC-211 | B | C | Comparison |
| OEL-412 | TC-212 | B | C | Comparison |
| OEL-413 | TC-213 | B | D | Comparison |
| OEL-414 | TC-214 | B | D | Comparison |
| OEL-415 | TC-215 | A | B | Present invention |
| OEL-416 | TC-216 | A | A | Present invention |
| OEL-417 | TC-217 | B | B | Present invention |
| OEL-418 | TC-218 | B | B | Present invention |
| OEL-419 | TC-219 | B | B | Present invention |
| OEL-420 | TC-220 | A | B | Present invention |
| OEL-421 | TC-221 | B | D | Comparison |
| OEL-422 | TC-222 | B | D | Comparison |
| OEL-423 | TC-223 | B | C | Comparison |

It became clear from the evaluation results shown in Table 4 that the luminescence uniformity of organic EL elements OEL-411 to OEL-414, and OEL-421 to OEL-423 were remarkably deteriorated after subjected to heating at 80° C. and 60% RH for 30 minutes (forced aging), while the luminescence uniformity of organic EL elements OEL-401 to OEL-410, and OEL-415 to OEL-420 of the present invention were highly stable even after subjected to heating (forced aging).

### Example 5

### Preparation of Transparent Electrode TC-501: Present Invention

Transparent electrode TC-501 was produced in the same manner as preparation of transparent electrode TC-101 in Example 1, except that the silver nanowires were replaced with SWCNT (HiPcoR monolayer carbon nanotubes, made by Unidym Co., Ltd.) and the amount of SWCNT was adjusted to be 50 mg/m².

### Preparation of Organic Electroluminescence Element (Organic EL Element)

Organic EL element OLE-501 was produced and evaluated like as in Example 3 by using the obtained transparent electrode as the 1^{st} electrode (anode electrode). It was confirmed that the produced organic EL element OLE-501 emitted light uniformly in the same manner as OLE-101. Moreover, uniform luminescence was observed in the whole of the organic EL element even after subjected to heating (forced aging) at 80° C. and 60% RH for 30 minutes.

### Example 6

### Preparation of Transparent Electrode TC-601: Present Invention

Transparent electrode TC-601 was produced in the same manner as preparation of transparent electrode TC-201 described in Example 2, except that the silver nanowires were replaced with SWCNT (HiPcoR monolayer carbon nanotubes, made by Unidym Co., Ltd.), without using the silver nanowire removing agent and the dispersion liquid was applied on the substrate by coating through the printing plate provided with a printing pattern having a stripe shape of 10 mm.

### Preparation of Organic Electroluminescence Element (Organic EL Element)

Organic EL element OLE-601 was produced and evaluated like as in Example 3 by using the obtained transparent electrode as the 1^{st} electrode (anode electrode). It was confirmed that the produced organic EL element OLE-601 emitted light uniformly in the same manner as OLE-201. Moreover, uniform luminescence was observed in the whole of the organic EL element even after subjected to heating (forced aging) at 80° C. and 60% RH for 30 minutes.

1-6. (canceled)

7. A method for forming the transparent electrode comprising the steps of:
applying an aqueous dispersion containing water, a metal nanowire, a conductive polymer and a water soluble binder resin on a transparent substrate to form a transparent conductive layer,
applying a metal nanowire removing agent on the transparent conductive layer to form a patterned transparent conductive layer,
wherein the water soluble binder resin contains a low molecular weight component in an amount of 0 to 5 weight % based on a weight of the water soluble binder resin, provided that the low molecular weight component has a number average molecular weight of 1,000 or less measured by GPC.

8. A method for forming the transparent electrode of claim 1,
wherein the transparent conductive layer is produced by the sequential steps of:
applying a first coating liquid containing a metal nanowire on a transparent substrate to form a first transparent conductive layer; and
applying a second coating liquid containing water, a conductive polymer and a water soluble binder resin on the first transparent conductive layer to form a second transparent conductive layer.

9. The method for forming a transparent electrode of claim 1,
wherein at least one hydroxyl group is contained in a recurring unit which forms the water soluble binder resin.

10. The method for forming a transparent electrode of claim 1,
wherein the water soluble binder resin contains a structure represented by Formula (1): 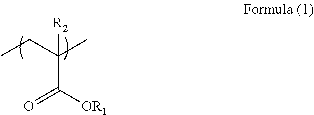
wherein R₁ represents a group which contains at least one hydroxyl group, and R₂ represents a hydrogen atom or a methyl group.

11. The method for forming a transparent electrode of claim 1,
wherein the metal nanowire is a silver nanowire.
